(19) United States
(12) Patent Application Publication
(10) Pub. No.: US 2012/0205822 A1
(43) Pub. Date: Aug. 16, 2012

(54) RESIN COMPOSITION FOR ENCAPSULATING SEMICONDUCTOR AND SEMICONDUCTOR DEVICE USING THE RESIN COMPOSITION

(76) Inventor: Yusuke Tanaka, Shinagawa-ku (JP)

(21) Appl. No.: 13/503,884

(22) PCT Filed: Oct. 19, 2010
(86) PCT No.: PCT/JP2010/006176

§ 371 Date: Apr. 25, 2012

(30) Foreign Application Priority Data
Oct. 26, 2009 (JP) 2009-245304

(51) Int. Cl. H01L 23/29; C08K 5/13; C09D 163/00

(52) U.S. Cl. 257/788; 523/400; 523/456; 257/E23.119

(57) ABSTRACT

Disclosed are a resin composition for encapsulating a semiconductor containing a phenol resin (A), an epoxy resin (B) and an inorganic filler (C), wherein the phenol resin (A) contains a polymer (a1) having a structure represented by the general formula (1), and the epoxy resin (B) contains at least one kind of epoxy resin selected from the group consisting of a triphenol methane type epoxy resin, a naphthol type epoxy resin and a dihydroanthracene type epoxy resin, and a semiconductor device, obtained by encapsulating a semiconductor element with a cured product of the resin composition for encapsulating a semiconductor.

### TECHNICAL FIELD

The present invention relates to a resin composition for encapsulating a semiconductor and a semiconductor device using the resin composition.

### BACKGROUND ART

A semiconductor device has been encapsulated for the purposes of protecting a semiconductor element, ensuring electric insulation and achieving easy handling property. For encapsulation of a semiconductor device, an epoxy resin composition has been mainly used for encapsulation by transfer molding because the epoxy resin composition is excellent in the productivity, cost, reliability and the like. In response to the market requirements of reduction in size, lightness and high performance of electronic devices, a novel joint technology such as surface mounting has been developed and commercialized, in addition to high integration of semiconductor elements, and miniaturization and high density of semiconductor devices. This technical trend has also influenced on a resin composition for encapsulating a semiconductor, and required performance has been upgraded and diversified year by year.

For example, as for solders used for surface mounting, use of lead-free solder instead has been promoted against the background of environmental problems. The melting point of lead-free solders is higher than that of the conventional lead/tin solders, and the reflow mounting temperature is increased from conventional 220 to 240 degrees centigrade of lead/tin solders, to 240 to 260 degrees centigrade, so that resin cracks are easily formed or detachment easily occurs inside the semiconductor device, and solder resistance is not sufficient in the conventional encapsulating resin composition in some cases.

Furthermore, for the purpose of imparting flame retardance, a bromine-containing epoxy resin and an antimony oxide have been used as a flame retardant in the conventional encapsulating resin composition. However, there is a growing opportunity to eliminate such compounds from the viewpoints of recent protection of the environment and improvement in the safety.

Furthermore, in recent years, electronic devices such as cars and mobile phones which are intended for outdoor use have come into wide use. In these applications, the operational reliability under severer environment than the conventional personal computers or household electric appliances has been in demand. In particular, high temperature storage life has been demanded as one of mandatory requirements in automotive applications, so that it is necessary to maintain operation and function of a semiconductor device at a high temperature of 150 to 180 degrees centigrade.

As a conventional technology, there have been proposed a method of enhancing high temperature storage life and solder resistance by combining an epoxy resin having a naphthalene skeleton and a phenol resin curing agent having a naphthalene skeleton (for example, see Patent Documents 1 and 2), and a method of enhancing high temperature storage life and flame resistance by combining a phosphorus containing compound (for example, see Patent Documents 3 and 4). However, it is hard to mention that a balance among flame resistance, continuous molding property and solder resistance is sufficient. As described above, with miniaturization and popularization of automotive electronic devices, there has been demanded an encapsulating resin composition which is well balanced among flame resistance, solder resistance, high temperature storage life and continuous molding property.

### RELATED DOCUMENT

### Patent Document

Patent Document 1: Japanese Unexamined Patent Application Publication No. 2007-31691
Patent Document 2: Japanese Unexamined Patent Application Publication No. Hei 06-216280
Patent Document 3: Japanese Unexamined Patent Application Publication No. 2003-292731
Patent Document 4: Japanese Unexamined Patent Application Publication No. 2004-43613

### DISCLOSURE OF THE INVENTION

The present invention is to provide an encapsulating resin composition which exhibits flame retardance without using a halogen compound and an antimony compound, and is excellent in a balance among solder resistance, high temperature storage life and continuous molding property at a higher level than conventional ones, and a semiconductor device excellent in the reliability using the encapsulating resin composition.

According to the present invention, there is provided a resin composition for encapsulating a semiconductor containing a phenol resin (A), an epoxy resin (B) and an inorganic filler (C), in which the aforementioned phenol resin (A) contains a polymer (a1) having a structure represented by the general formula (1), and

the epoxy resin (B) contains at least one kind of epoxy resin selected from the group consisting of a triphenol methane type epoxy resin, a naphthol type epoxy resin and a dihydroanthracene type epoxy resin,

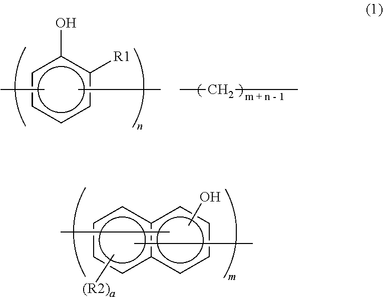

wherein, in the general formula (1), R1 is a hydrocarbon group having 1 to 6 carbon atoms; R2 is a hydrocarbon group having 1 to 6 carbon atoms or an aromatic hydrocarbon group having 6 to 14 carbon atoms, and may be the same or different from each other; a is an integer of from 0 to 2; m and n are each independently an integer of from 1 to 10; m+n is 2 or more; and the structural units represented by the repetition number m and the structural units represented by the repetition number n may be arranged in line continuously, alternately or at random, but necessarily each have a structure having —CH2- between them.

According to one embodiment of the present invention, in the aforementioned resin composition for encapsulating a semiconductor, the aforementioned epoxy resin (B) contains at least one kind of epoxy resin selected from the group consisting of an epoxy resin (b1) represented by the general formula (2), an epoxy resin (b2) represented by the general formula (3) and an epoxy resin (b3) represented by the general formula (4),

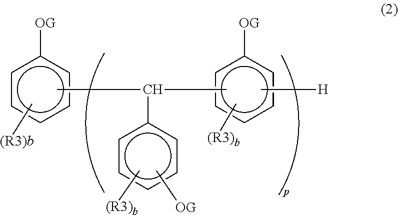

wherein, in the general formula (2), R3 is a hydrocarbon group having 1 to 6 carbon atoms or an aromatic hydrocarbon group having 6 to 14 carbon atoms, and may be the same or different from each other; b is an integer of from 0 to 4; p is an integer of from 1 to 10; and G is an organic group containing a glycidyl group,

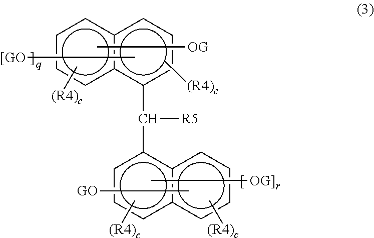

wherein, in the general formula (3), R4 is a hydrocarbon group having 1 to 6 carbon atoms or an aromatic hydrocarbon group having 6 to 14 carbon atoms, and may be the same or different from each other; R5 is a hydrogen atom, a hydrocarbon group having 1 to 6 carbon atoms or an aromatic hydrocarbon group having 6 to 14 carbon atoms; c is an integer of from 0 to 5; q and r are each independently an integer of 0 or 1; and G is an organic group containing a glycidyl group,

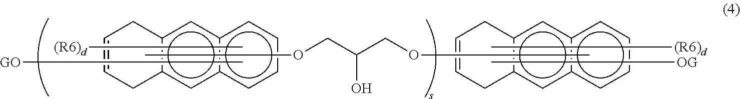

wherein, in the general formula (4), R6 is a hydrocarbon group having 1 to 6 carbon atoms or an aromatic hydrocarbon group having 6 to 14 carbon atoms, and may be the same or different from each other; d is an integer of from 0 to 8; s is an integer of from 0 to 10; and G is an organic group containing a glycidyl group.

According to one embodiment of the present invention, in the aforementioned resin composition for encapsulating a semiconductor, the ICI viscosity at 150 degrees centigrade of the aforementioned phenol resin (A) is from 1.0 to 7.0 dPa·sec.

According to one embodiment of the present invention, in the aforementioned resin composition for encapsulating a semiconductor, R1 in the general formula (1) is a methyl group.

According to one embodiment of the present invention, in the aforementioned resin composition for encapsulating a semiconductor, the ratio of the polymer component in which (m,n) is (2,1) in the aforementioned phenol resin (A) measured by the gel permeation chromatography (GPC) method is from 30 to 80% by area.

According to one embodiment of the present invention, the aforementioned resin composition for encapsulating a semiconductor further contains a curing agent, and the aforementioned phenol resin (A) is contained in an amount of 50 to 100 parts by mass in 100 parts by mass of the curing agent.

According to one embodiment of the present invention, in the aforementioned resin composition for encapsulating a semiconductor, at least one kind of the aforementioned epoxy resin selected from the group consisting of a triphenol methane type epoxy resin, a naphthol type epoxy resin and a dihydroanthracene type epoxy resin is contained in an amount of 50 to 100 parts by mass in 100 parts by mass of the aforementioned epoxy resin (B).

According to one embodiment of the present invention, in the aforementioned resin composition for encapsulating a semiconductor, at least one kind of the aforementioned epoxy resin selected from the group consisting of the epoxy resin (b1) represented by the general formula (2), the epoxy resin (b2) represented by the general formula (3) and the epoxy resin (b3) represented by the general formula (4) is contained in an amount of 50 to 100 parts by mass in 100 parts by mass of the aforementioned epoxy resin (B).

According to one embodiment of the present invention, in the aforementioned resin composition for encapsulating a semiconductor, the content ratio of the aforementioned inorganic filler (C) is from 70 to 93% by mass, based on the total resin composition.

According to one embodiment of the present invention, in the aforementioned resin composition for encapsulating a semiconductor, the content ratio of the aforementioned inorganic filler (C) is from 80 to 93% by mass, based on the total resin composition.

According to one embodiment of the present invention, in the aforementioned resin composition for encapsulating a semiconductor, the aforementioned epoxy resin (b1) represented by the general formula (2) is contained in an amount of 50 to 100 parts by mass in 100 parts by mass of the aforementioned epoxy resin (B).

According to one embodiment of the present invention, the aforementioned resin composition for encapsulating a semiconductor further contains a curing accelerator (D).

According to one embodiment of the present invention, in the aforementioned resin composition for encapsulating a semiconductor, the aforementioned curing accelerator (D) contains at least one kind of curing accelerator selected from the group consisting of a tetra-substituted phosphonium compound, a phosphobetaine compound, an adduct of a phosphine compound and a quinone compound, and an adduct of a phosphonium compound and a silane compound.

According to one embodiment of the present invention, the aforementioned resin composition for encapsulating a semiconductor further contains a compound (E) in which a hydroxyl group is bonded to each of two or more adjacent carbon atoms constituting an aromatic ring.

According to one embodiment of the present invention, the aforementioned resin composition for encapsulating a semiconductor further contains a coupling agent (F).

According to one embodiment of the present invention, the aforementioned resin composition for encapsulating a semiconductor further contains an inorganic flame retardant (G).

According to one embodiment of the present invention, in the aforementioned resin composition for encapsulating a semiconductor, the aforementioned epoxy resin (b2) represented by the general formula (3) is contained in an amount of 50 to 100 parts by mass in 100 parts by mass of the aforementioned epoxy resin (B).

According to one embodiment of the present invention, in the aforementioned resin composition for encapsulating a semiconductor, the aforementioned epoxy resin (b3) represented by the general formula (4) is contained in an amount of 50 to 100 parts by mass in 100 parts by mass of the aforementioned epoxy resin (B).

According to the present invention, there is provided a semiconductor device obtained by encapsulating a semiconductor element with a cured product of the aforementioned resin composition for encapsulating a semiconductor.

According to the present invention, it is possible to obtain a resin composition for encapsulating a semiconductor which exhibits flame retardance without using a halogen compound and an antimony compound, and is excellent in a balance among solder resistance, high temperature storage life and continuous molding property at a higher level than conventional ones, and a semiconductor device excellent in the reliability using the resin composition for encapsulating a semiconductor.

### BRIEF DESCRIPTION OF THE DRAWINGS

FIG. 1 is a view illustrating a cross-section structure of an example of a semiconductor device using the resin composition for encapsulating a semiconductor according to the present invention.

FIG. 2 is a view illustrating a cross-section structure of an example of a one-side encapsulated semiconductor device using the resin composition for encapsulating a semiconductor according to the present invention.

FIG. 3 is a GPC chart of a phenol resin 1 used in Examples.

FIG. 4 is an FD-MS chart of a phenol resin 1 used in Examples.

### DESCRIPTION OF EMBODIMENTS

Preferred embodiments of the resin composition for encapsulating a semiconductor and the semiconductor device according to the present invention will be described in detail with reference to the drawings. Incidentally, in the description of the drawings, the same components are assigned the same reference numerals and appropriate explanations thereof will be omitted.

The resin composition for encapsulating a semiconductor of the present invention includes a phenol resin (A) containing a polymer (a1) having a structure represented by the general formula (1), an epoxy resin (B) containing at least one kind of epoxy resin selected from the group consisting of a triphenol methane type epoxy resin, a naphthol type epoxy resin and a dihydroanthracene type epoxy resin, and an inorganic filler (C). In addition, the semiconductor device of the present invention is obtained by encapsulating a semiconductor element with a cured product of the aforementioned resin composition for encapsulating a semiconductor. Hereinafter, the present invention will be described in detail.

First, the resin composition for encapsulating a semiconductor of the present invention will be described. The resin composition for encapsulating a semiconductor of the present invention includes a phenol resin (A) containing a polymer (a1) having a structure represented by the general formula (1) (hereinafter referred to as the phenol resin (A)),

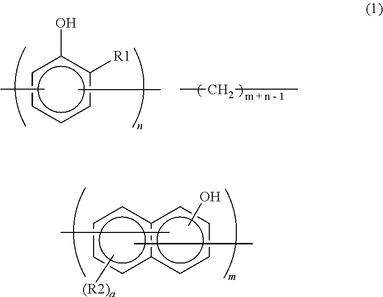

wherein, in the general formula (1), R1 is a hydrocarbon group having 1 to 6 carbon atoms; R2 is a hydrocarbon group having 1 to 6 carbon atoms or an aromatic hydrocarbon group having 6 to 14 carbon atoms, and may be the same or different from each other; a is an integer of from 0 to 2; m and n are each independently an integer of from 1 to 10; m+n is 2 or more; and the structural units represented by the repetition number m and the structural units represented by the repetition number n may be arranged in line continuously, alternately or at random, but necessarily each have a structure having —CH2- between them.

The phenol resin (A) is excellent in flame resistance and also excellent in hydrophobic property because of the presence of a naphthol skeleton in its molecule, and has high solder resistance because of the effect of lowering the elastic modulus at a solder reflow temperature. In general, a novolac resin having a naphthol skeleton is hardly melt-kneaded because the softening point is high and the viscosity is high, so that the flowability is not enough. Thus, such a naphthol-containing novolac resin is hardly applicable to a molding material in many cases. However, the phenol resin (A) used in the present invention has the viscosity and softening point which are appropriately reduced because of the presence of an alkyl (R1) substituted phenol skeleton in its molecule. Furthermore, moisture resistance of the phenol resin (A) is improved because of the alkyl group (R1). Furthermore, the phenol resin (A) exhibits excellent continuous molding property because of the alkyl group (R1) at an ortho position as compared to the alkyl group (R1) at a para position. Furthermore, since the alkyl-substituted phenol skeleton and the naphthol skeleton are bonded in a relatively short distance because of the presence of —CH2- in the molecule of the phenol resin (A), the density of the hydroxyl group and naphthalene is increased and as a result, the phenol resin (A) may exhibit excellent reactivity with the epoxy resin and a cured product thereof may exhibit excellent heat resistance.

The repetition numbers m and n of respective structural units in the polymer (a1) having a structure represented by the general formula (1) contained in the phenol resin (A) are each independently an integer of from 1 to 10, and m+n is 2 or more. Within this range, the resin composition may be well kneaded when heating, melting and kneading. It is preferable that m is from 1 to 6 and n is from 1 to 6. Within this range, the resin composition may be well formed. The phenol resin (A) obtained by synthesis has an arbitrary molecular weight distribution. However, from the viewpoint of a balance among curability, flame resistance, heat resistance and flowability, a main component may be preferably a component in which the value of m+n is 3 and 4, and more preferably a (m,n)=(2,1) component. The (m,n)=(2,1) component is excellent in solder resistance and flame resistance, and also excellent in the flowability because the ratio of the naphthol skeleton in the component is high. The content ratios of these components are not particularly limited, but the following ranges are preferable. In the gel permeation chromatography (GPC) method, the content ratio of the (m,n)=(2,1) component is preferably from 30 to 80% by area and more preferably from 40 to 70% by area. In order to have the aforementioned preferable ranges of the content ratios of respective (m, n) components, the ratios can be controlled by the methods described below.

In the present invention, gel permeation chromatography (GPC) is measured in the following manner. A GPC device is equipped with a pump, an injector, a guard column, a column and a detector. For the measurement, tetrahydrofuran (THF) is used as a solvent. The flow rate of the pump is 0.5 ml/minute. A plurality of commercial guard columns (for example, TSK GUARDCOLUMN HHR-L, commercially available from Tosoh Corporation, diameter: 6.0 mm, tube length: 40 mm) as a guard column and a plurality of commercial polystyrene gel columns (TSK-GEL GMHHR-L, commercially available from Tosoh Corporation, diameter: 7.8 mm, tube length: 30 mm) as a column are used, which are connected in series. A differential refractometer (RI detector, for example, a differential refractive index (RI) detector, W2414, commercially available from Waters Corporation) is used as a detector. Before the measurement, the inside of the guard column, column and detector is stabilized at a temperature of 40 degrees centigrade. A THF solution of the phenol resin in which its concentration is adjusted to 3 to 4 mg/ml is prepared as a sample and the solution is injected from an injector of about 50 to 150 μl for the measurement. For the analysis of the sample, a calibration curve produced by the use of a monodispersed polystyrene (hereinafter referred to as PS) standard sample is used. The calibration curve is obtained by plotting the logarithmic value of the molecular weight of PS versus the peak detection time (retention time) of PS, and making a straight line using a regression equation. As the standard PS sample for producing a calibration curve, there are used Model S-1.0 (peak molecular weight: 1,060), S-1.3 (peak molecular weight: 1,310), S-2.0 (peak molecular weight: 1,990), S-3.0 (peak molecular weight: 2,970), S-4.5 (peak molecular weight: 4,490), S-5.0 (peak molecular weight: 5,030), S-6.9 (peak molecular weight: 6,930), S-11 (peak molecular weight: 10,700) and S-20 (peak molecular weight: 19,900), all of which are Shodex standard SL-105 series commercially available from Showa Denko K.K.

The values of m and n in the general formula (1) may be obtained by the FD-MS measurement. With respect to respective peaks detected by the FD-MS analysis and measured in the detected mass (m/z) range of 50 to 2,000, the molecular weight from the detected mass (m/z) and the values of the repetition numbers (m, n) may be obtained, and respective peaks in the GPC measurement are matched, whereby respective (m, n) components may be identified. Furthermore, the intensity ratio of respective peaks is further determined as the content ratio (mass ratio).

The resin viscosity of the phenol resin (A) is preferably from 1.0 to 7.0 dPa·sec, more preferably from 1.5 to 4.5 dPa·sec and particularly preferably from 2.0 to 4.0 dPa·sec in the measurement of the ICI viscosity at 150 degrees centigrade. When the lower limit of the ICI viscosity is within the above range, the curability and flame resistance of the resin composition become excellent. On the other hand, when the upper limit is within the above range, the flowability becomes excellent.

A method for synthesizing the phenol resin (A) used in the present invention is not particularly limited. Examples of the synthesis method include a method involving subjecting an alkyl-substituted phenol compound, a naphthol compound and formaldehydes to polycondesation under an acid catalyst (hereinafter referred to as the first synthesis method), a method involving subjecting alkyl-substituted phenols and formaldehydes to methylolation under a basic catalyst, followed by addition of naphthols and an acid catalyst thereto and to co-condensation (hereinafter referred to as the second synthesis method), and the like. After completion of the reaction, the acid catalyst in use is neutralized or washed with water, and remained monomers and moisture are further removed by heating and distillation under reduced pressure.

The naphthol compound is not particularly limited as long as it has a structure such that one hydroxyl group is bonded to a naphthalene ring, and examples thereof include α-naphthols such as α-naphthol, 2-methyl-1-naphthol, 3-methyl-1-naphthol, 4-methyl-1-naphthol, 6-methyl-1-naphthol, 7-methyl-1-naphthol, 8-methyl-1-naphthol, 9-methyl-1-naphthol, 3-methyl-2-naphthol, 5-methyl-1-naphthol, 6,7-dimethyl-1-naphthol, 5,7-dimethyl-1-naphthol, 2,5,8-trimethyl-1-naphthol, 2,6-dimethyl-1-naphthol, 2,3-dimethyl-1-naphthol, 2-methyl-3-phenyl-1-naphthol, 2-methyl-3-ethyl-1-naphthol and the like; and β-naphthols such as β-naphthol, 1,6-di-tert-butylnaphthalene-2-ol, 6-hexyl-2-naphthol and the like. Among these compounds, preferably used are α-naphthol, β-naphthol and 6-hexyl-2-naphthol from the viewpoints of high yield and high reaction rate in the synthesis of a phenol resin. Furthermore, for these naphthol compounds, the raw material cost is cheap and the reactivity with the epoxy resin is excellent.

The alkyl-substituted phenol compound is not particularly limited as long as it has a structure such that an alkyl substituent is bonded to the second position (ortho position) of the phenol structure. Herein, this alkyl group is a substituent R1 in the phenol resin (A) represented by the general formula (1) to be obtained. The bonding position of the alkyl substituent of R1 in the general formula (1) is the ortho position, whereby the phenol resin (A) exhibits excellent continuous molding property. Even though the reason is not clear, the following model is considered. In general, in a phenol compound and a naphthol compound, carbon atoms at the ortho position and the para position have high reactivity with respect to the hydroxyl groups, and are preferentially bonded (referred to as ortho-para orientation). Herein, as one example of a phenol skeleton having the alkyl group (R1) at the para position or the ortho position, a structure such that two β-naphthols (or α-naphthols may be good) are bonded to para-cresol via a methylene group (—CH2-) is taken as a model. In this case, due to the aforementioned orientation, the chemical structure has a high symmetry focusing on para-cresol, in which methylene groups are bonded to the second position and the sixth position of cresol, and further bonded to the first position of β-naphthol. In such a model structure, three hydroxyl groups form intramolecular hydrogen bonds because their three-dimensional positions are remarkably close, and further two bulky naphthalenes are symmetrically surrounding the periphery thereof, so that the hydroxyl groups are hard to react with the epoxy groups with good efficiency. That is, when the resin composition is molded, three hydroxyl groups cannot form a crosslinked structure with the epoxy groups with good efficiency and as a result, continuous molding property is considered to be deteriorated. On the other hand, in the aforementioned model structure, when ortho-cresol is used, β-naphthols are bonded to the fourth position and the sixth position of cresol via a methylene group, so that the symmetry of the bonding positions of naphthalenes is low, three hydroxyl groups are properly dispersed and the aforementioned factors of inhibiting curing are less influential, as compared to the case which para-cresol is used. As a result, it is considered that a resin composition excellent in continuous molding property is obtained. Furthermore, from the viewpoints of the aforementioned model structure and an increase in the content ratio of the (m,n)=(2,1) component, it is preferable that hydrogen atoms are bonded to carbon atoms at the fourth position and the sixth position of the alkyl-substituted phenol structure.

The alkyl substituent of R1 in the general formula (1) is a hydrocarbon group having 1 to 6 carbon atoms, and examples of the alkyl-substituted phenol compound bonded to the second position (ortho position) of the phenol structure include ortho-cresol, 2,3-xylenol, 2,5-xylenol, 2-ethylphenol, 2-propylphenol, 2-butylphenol, 2-pentylphenol, 2-hexylphenol and the like. These may be used singly or may be used in combination of two or more kinds.

Meanwhile, when phenol without containing an alkyl substituent of R1 in the general formula (1) is used, the molecular weight of the obtained phenol resin is easily increased or the phenol resin easily takes a branched structure, so that the viscosity is increased and the flowability of the resin composition is impaired in some cases; therefore, such a phenol is not preferable. When the number of carbon atoms of the alkyl substituent of R1 in the general formula (1) is greater than 7, due to the effect of steric hindrance, the reactivity of adjacent hydroxyl groups is impaired and the curability of the resin composition is lowered; therefore, such a number is not preferable. Concrete examples of the alkyl substituent of R1 in the general formula (1) include a methyl group, an ethyl group, a propyl group, an isopropyl group, a butyl group, a pentyl group, a hexyl group and the like. Among these, preferably used is a methyl group from the viewpoint of an excellent balance among flowability, curability and moisture resistance of the resin composition.

The alkyl substituent of R1 in the general formula (1) is a methyl group, and examples of the alkyl-substituted phenol compound bonded to the second position (ortho position) of the phenol structure include ortho-cresol, 2,3-xylenol, 2,5-xylenol and the like. These may be used singly or may be used in combination of two or more kinds. Among these, preferably used is ortho-cresol from the viewpoint of a balance among flowability, curability, moisture resistance and continuous molding property.

As the formaldehydes, a substance which is a formaldehyde generation source, such as an aqueous solution of para-formaldehyde, trioxane, formaldehyde or the like, or a solution of such formaldehydes, may be used. Usually, an aqueous solution of formaldehyde is preferably used in view of the workability and the cost.

As the basic catalyst used in the second synthesis method, a basic catalyst known in the usual synthesis of a resol type phenol resin may be used. For example, sodium hydroxide, potassium hydroxide, calcium hydroxide, magnesium hydroxide, ammonia, trimethylamine and the like can be used. These may be used singly or may be used in combination of two or more kinds. Furthermore, as the acid catalyst used in the first synthesis method and the second synthesis method, an acid catalyst known in the usual synthesis of a novolac type phenol resin may be used. Examples thereof include inorganic acids such as sulfuric acid, hydrochloric acid, phosphoric acid, phosphorous acid and the like; organic acids such as oxalic acid, formic acid, organic phosphonate, para-toluenesulfonic acid, dimethyl sulfate and the like; zinc acetate, nickel acetate and the like. These may be used singly or may be used in combination of two or more kinds.

As a method for controlling the respective (m, n) components, the following methods may be exemplified.

Control of the m+n≦2 Component: In case of the first synthesis method, the m+n≦2 component may be reduced by a method involving reducing the mixing amount of formaldehydes, controlling the molecular weight of the phenol resin obtained by synthesis according to a method such as atmospheric distillation, vacuum distillation, steam distillation or washing with water, or the like. In this case, as preferable distillation conditions, the temperature is equal to or more than 50 degrees centigrade and equal to or less than 250 degrees centigrade. When the distillation temperature is less than 50 degrees centigrade, the efficiency by distillation is worsened; therefore such a temperature is not preferable from the viewpoint of the productivity. When it exceeds 250 degrees centigrade, decomposition and high molecular weight of the phenol resin are complicated; therefore, such a temperature is not preferable either. Specifically, by the vacuum distillation under the conditions of a temperature of 120 to 200 degrees centigrade and a pressure of 5,000 Pa, the monomer component such as alkyl-substituted phenols, naphthols or the like may be removed with good efficiency, and by the vacuum steam distillation under the conditions of a temperature of 200 to 250 degrees centigrade and a pressure of 5,000 Pa, the m+n≦2 component may be removed with good efficiency. As the method of controlling the molecular weight by washing with water, water is added to a phenol resin which is fully dissolved in an organic solvent, and the resulting mixture is stirred at a temperature of 20 to 150 degrees centigrade at ordinary pressure or under pressure to separate an aqueous phase and an organic phase by allowing to stand or centrifugal separation, and to remove the aqueous phase out of the system, whereby it is possible to reduce the low molecular weight component (m+n≦2 component) dissolved in the aqueous phase. In case of the second synthesis method, when phenols and formaldehydes are subjected to methylolation under a basic catalyst, the m+n≦2 component may be reduced by a method involving reducing the mixing amount of formaldehydes, controlling the molecular weight of the phenol resin obtained by synthesis according to a method such as atmospheric distillation, vacuum distillation, steam distillation or washing with water, or the like. As preferable distillation conditions, similarly to the first synthesis method, the temperature is equal to or more than 50 degrees centigrade and equal to or less than 250 degrees centigrade.

Control of m+n≧4 Component: In case of the first synthesis method, the m+n≧4 component may be reduced by a method involving reducing the amount of the acid catalyst used for the synthesis, lowering the reaction temperature during the reaction with the acid catalyst, controlling the molecular weight by extraction of the phenol resin obtained by synthesizing, or the like. As the method of controlling the molecular weight by extraction, a nonpolar solvent having a low solubility to a phenol resin such as toluene, xylene or the like is added to a phenol resin, or a phenol resin dissolved in a polar solvent such as alcohol or the like, and the resulting mixture is stirred at a temperature of 20 to 150 degrees centigrade at ordinary pressure or under pressure to separate a nonpolar solvent phase and other component phase by allowing to stand or centrifugal separation, and to remove the nonpolar solvent phase out of the system, whereby it is possible to remove the high molecular weight component dissolved in the nonpolar solvent phase. By these procedures, the amount of the m+n≧4 component can be reduced. In case of the second synthesis method, the m+n≧4 component may be reduced by a method involving reducing the amount of the acid catalyst used for the second stage reaction, lowering the reaction temperature during the reaction with the acid catalyst, controlling the molecular weight by extraction of the phenol resin obtained by synthesizing, or the like.

Control of m+n=3 Component: With respect to the m+n=3 component, various aforementioned control methods may be combined to control the component. As a method of controlling the (m, n)=(2,1) component, the (m,n)=(2,1) component may be increased by a method involving using β-naphthol for naphthols, increasing the mixing amount of naphthols in the first synthesis method, using the second synthesis method, increasing the mixing amount of formaldehydes in the second synthesis method, or the like.

In the resin composition for encapsulating a semiconductor of the present invention, other curing agents may be used together in the ranges in which the effect by the use of the aforementioned phenol resin (A) is not impaired. The curing agent which may be used together is not particularly limited, and examples thereof include a polyaddition type curing agent, a catalyst type curing agent, a condensation type curing agent and the like.

Examples of the polyaddition type curing agent include polyamine compounds containing dicyandiamide, organic dihydrazide and the like; acid anhydrides containing alicyclic acid anhydride such as hexahydrophthalic anhydride, methyl tetrahydrophthalic anhydride and the like, and aromatic acid anhydride such as trimellitic anhydride, pyromellitic anhydride, benzophenonetetracarboxylic acid and the like; polyphenol compounds such as a novolac type phenol resin, a phenol polymer and the like; polymercaptan compounds such as polysulfide, thioester, thioether and the like; isocyanate compounds such as isocyanate prepolymer, blocked isocyanate and the like; and organic acids such as a carboxylic acid-containing polyester resin and the like, in addition to aliphatic polyamines such as diethylenetriamine, triethylenetetramine, meta-xylylenediamine and the like, and aromatic polyamines such as diaminodiphenyl methane, m-phenylenediamine, diaminodiphenyl sulfone and the like.

Examples of the catalyst type curing agent include tertiary amine compounds such as benzyldimethylamine, 2,4,6-tris dimethylaminomethylphenol and the like; imidazole compounds such as 2-methylimidazole, 2-ethyl-4-methylimidazole and the like; and Lewis acids such as BF3 complexes and the like.

Examples of the condensation type curing agent include phenol resin type curing agents such as a novolac type phenol resin, a resol type phenol resin and the like; urea resins such as urea resins containing a methylol group; and melamine resins such as melamine resins containing a methylol group.

Among these, preferably used are phenol resin type curing agents from the viewpoint of a balance among flame resistance, moisture resistance, electric characteristics, curability, storage stability and the like. The phenol resin type curing agent refers to monomers, oligomers and polymers having two or more phenolic hydroxyl groups in one molecule. The molecular weight and molecular structure thereof are not particularly limited. Examples of the phenol resin type curing agent include novolac type resins such as a phenol novolac resin, a cresol novolac resin, a naphthol novolac resin and the like; polyfunctional phenol resins such as a triphenol methane type phenol resin and the like; modified phenol resins such as a terpene-modified phenol resin, a dicyclopentadiene-modified phenol resin and the like; aralkyl type resins such as a phenol aralkyl resin having a phenylene skeleton and/or a biphenylene skeleton, a naphthol aralkyl resin having a phenylene skeleton and/or a biphenylene skeleton and the like; and bisphenol compounds such as bisphenol A, bisphenol F and the like. These may be used singly or may be used in combination of two or more kinds. Among these, preferably used are those having a hydroxyl equivalent of from 90 to 250 g/eq from the viewpoint of curability.

When such other curing agents are used together, the mixing ratio of the phenol resin (A) is preferably equal to or more than 50% by mass, more preferably equal to or more than 60% by mass and particularly preferably equal to or more than 70% by mass, based on the total curing agent. When the mixing ratio is within the above range, the effect of improving flame resistance and solder resistance may be achieved while maintaining excellent flowability and curability.

The lower limit of the ratio of the curing agent in the resin composition is not particularly limited, but it is preferably equal to or more than 0.8% by mass and more preferably equal to or more than 1.5% by mass, based on the total resin composition. When the lower limit of the mixing ratio is within the above range, sufficient flowability may be achieved. Meanwhile, the upper limit of the ratio of the curing agent in the resin composition is not particularly limited, but it is preferably equal to or less than 10% by mass and more preferably equal to or less than 8% by mass, based on the total resin composition. When the upper limit of the mixing ratio is within the above range, excellent solder resistance may be achieved.

For the resin composition for encapsulating a semiconductor of the present invention, there is used an epoxy resin (B) containing at least one kind of epoxy resin selected from the group consisting of a triphenol methane type epoxy resin, a naphthol type epoxy resin and a dihydroanthracene type epoxy resin. Preferably used are a triphenol methane type epoxy resin, a naphthol type epoxy resin and a dihydroanthracene type epoxy resin from the viewpoints of excellent curability, heat resistance, solder resistance and continuous molding property. In particular, a triphenol methane type epoxy resin is preferable from the viewpoints of high heat resistance, high curability and continuous molding property, a naphthol type epoxy resin is preferable from the viewpoints of high heat resistance and high flowability, and a dihydroanthracene type epoxy resin is preferable from the viewpoints of high heat resistance, low water absorption ratio and low warpage. Even though all these three kinds of epoxy resins are excellent in heat resistance, the order is a triphenol methane type epoxy resin, a naphthol type epoxy resin and a dihydroanthracene type epoxy resin when heat resistance is compared. It is preferable to select an epoxy resin according to properties required for a resin composition for encapsulating a semiconductor, in addition to heat resistance and/or high heat resistance. Two kinds from the aforementioned three kinds of epoxy resins can be used in combination or all three kinds thereof can be used at one time. Furthermore, from the viewpoint of moisture-resistant reliability of the obtained resin composition for encapsulating a semiconductor, Na+ ions or Cl— ions, which are ionic impurities, are preferably not contained in these epoxy resins as much as possible. From the viewpoint of curability of a semiconductor resin composition, the epoxy equivalent of the epoxy resin is preferably from 100 to 500 g/eq and more preferably from 150 to 210 g/eq. When the epoxy equivalent is within this range, the crosslink density of a cured product of the resin composition is increased, so that the cured product can have a high glass transition point.

The triphenol methane type epoxy resin used for the resin composition for encapsulating a semiconductor of the present invention is not particularly limited, but preferably used is an epoxy resin (b1) represented by the general formula (2) from the viewpoints of the curability and continuous molding property. Examples of the commercial product include E-1032H60 and YL6677, commercially available from Japan Epoxy Resin Co., Ltd., Tactix742 commercially available from Huntsman Corporation, and the like.

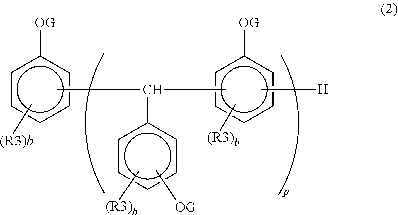

wherein, in the general formula (2), R3 is a hydrocarbon group having 1 to 6 carbon atoms or an aromatic hydrocarbon group having 6 to 14 carbon atoms, and may be the same or different from each other; b is an integer of from 0 to 4; p is an integer of from 1 to 10; and G is an organic group containing a glycidyl group.

The naphthol type epoxy resin used for the resin composition for encapsulating a semiconductor of the present invention is not particularly limited, but preferably used is an epoxy resin (b2) represented by the general formula (3) having two naphthalene skeletons from the viewpoint of the flowability. Examples of the commercial product include HP-4700, HP-4701, HP-4735, HP-4750 and HP-4770, commercially available from DIC Corporation, and the like.

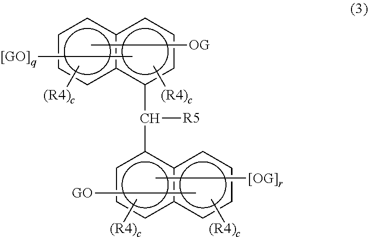

wherein, in the general formula (3), R4 is a hydrocarbon group having 1 to 6 carbon atoms or an aromatic hydrocarbon group having 6 to 14 carbon atoms, and may be the same or different from each other; R5 is a hydrogen atom, a hydrocarbon group having 1 to 6 carbon atoms or an aromatic hydrocarbon group having 6 to 14 carbon atoms; c is an integer of from 0 to 5; q and r are each independently an integer of 0 or 1; and G is an organic group containing a glycidyl group.

The dihydroanthracene type epoxy resin used for the resin composition for encapsulating a semiconductor of the present invention is not particularly limited, but preferably used is an epoxy resin (b3) represented by the general formula (4) from the viewpoints of low water absorption property and warpage. Examples of the commercial product include YX8800 commercially available from Japan Epoxy Resin Co., Ltd. and the like.

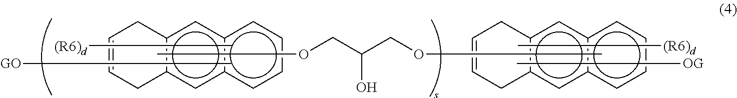

wherein, in the general formula (4), R6 is a hydrocarbon group having 1 to 6 carbon atoms or an aromatic hydrocarbon group having 6 to 14 carbon atoms, and may be the same or different from each other; d is an integer of from 0 to 8; s is an integer of from 0 to 10; and G is an organic group containing a glycidyl group.

In the resin composition for encapsulating a semiconductor of the present invention, other epoxy resins may be used together in the ranges in which the effect by the use of three kinds of the aforementioned epoxy resins is not impaired. Examples of the epoxy resin which may be used together include novolac type epoxy resins such as a phenol novolac type epoxy resin, a cresol novolac type epoxy resin and the like; aralkyl type epoxy resins such as a phenol aralkyl type epoxy resin having a phenylene skeleton, a naphthol aralkyl type epoxy resin having a phenylene skeleton, a phenol aralkyl type epoxy resin having a biphenylene skeleton, a naphthol aralkyl type epoxy resin having a biphenylene skeleton and the like; dihydroxynaphthalene type epoxy resins; triazine nucleus-containing epoxy resins such as triglycidyl isocyanurate, monoallyl diglycidyl isocyanurate and the like; and bridged cyclic hydrocarbon compound-modified phenol type epoxy resins such as a dicyclopentadiene-modified phenol type epoxy resin and the like. In consideration of moisture-resistant reliability of the epoxy resin composition for encapsulating a semiconductor, Na+ ions or Cl— ions, which are ionic impurities, are preferably contained in these epoxy resins as small as possible. From the viewpoint of curability, the epoxy equivalent is preferably equal to or more than 100 g/eq and equal to or less than 500 g/eq. These may be used singly or may be used in combination of two or more kinds.

When such other epoxy resins are used together, the mixing ratio of three kinds of the aforementioned epoxy resins is preferably equal to or more than 50% by mass, more preferably equal to or more than 60% by mass and particularly preferably equal to or more than 70% by mass, based on the total epoxy resin (B). When the mixing ratio is within the above range, the effect of improving excellent glass transition point and curability may be achieved.

The lower limit of the mixing amount of the total epoxy resin (B) in the resin composition for encapsulating a semiconductor is preferably equal to or more than 2% by mass and more preferably equal to or more than 4% by mass, based on the total amount of the resin composition for encapsulating a semiconductor. When the lower limit is within the above range, the obtained resin composition has excellent flowability. On the other hand, the upper limit of the mixing amount of the total epoxy resin (B) in the resin composition for encapsulating a semiconductor is preferably equal to or less than 15% by mass and more preferably equal to or less than 13% by mass, based on the total amount of the resin composition for encapsulating a semiconductor. When the upper limit is within the above range, the obtained resin composition has excellent solder resistance.

Incidentally, when only a phenol resin type curing agent is used as a curing agent, it is preferable that the phenol resin type curing agent and the epoxy resin are mixed such that the equivalent ratio (EP)/(OH) of the number of epoxy groups (EP) of the total epoxy resin to the number of phenolic hydroxyl groups (OH) of the total phenol resin type curing agent is equal to or more than 0.8 and equal to or less than 1.3. When the equivalent ratio is within the above range, sufficient curing properties may be obtained during molding of the resin composition to be obtained.

In the resin composition for encapsulating a semiconductor of the present invention, an inorganic filler (C) is used. The inorganic filler (C) used for the resin composition for encapsulating a semiconductor of the present invention is not particularly limited, but inorganic fillers which are generally used in the related field may be used. Examples thereof include fused silica, spherical silica, crystal silica, alumina, silicon nitride, aluminum nitride and the like. The particle diameter of the inorganic filler is preferably equal to or more than 0.01 μm and equal to or less than 150 μm from the viewpoint of filling property into a mold cavity.

The content of the inorganic filler in the resin composition for encapsulating a semiconductor is not particularly limited, but it is preferably equal to or more than 70% by mass, more preferably equal to or more than 80% by mass, further preferably equal to or more than 83% by mass, and particularly preferably equal to or more than 86% by mass, based on the total amount of the resin composition for encapsulating a semiconductor. When the lower limit of the content is within the above range, the moisture absorption amount of the cured product of the obtained resin composition for encapsulating a semiconductor can be reduced, decrease in strength can be suppressed, and accordingly a cured product having excellent solder resistance can be obtained. On the other hand, the upper limit of the content of the inorganic filler in the resin composition for encapsulating a semiconductor is preferably equal to or less than 93% by mass, more preferably equal to or less than 91% by mass and further preferably equal to or less than 90% by mass, based on the total amount of the resin composition for encapsulating a semiconductor. When the upper limit of the content is within the above range, the obtained resin composition has excellent flowability and excellent molding property. Incidentally, when metal hydroxides such as aluminum hydroxide, magnesium hydroxide and the like, or inorganic flame retardants such as zinc borate, zinc molybdate, antimony trioxide and the like to be described below are used, the total amount of the inorganic flame retardant and the aforementioned inorganic filler is preferably within the above range.

In the resin composition for encapsulating a semiconductor of the present invention, a curing accelerator (D) may be further used. The curing accelerator (D) has an action of accelerating a crosslinking reaction between the epoxy resin and the curing agent, and in addition thereto, an action of controlling a balance between flowability and curability during curing of the resin composition for encapsulating a semiconductor, and an action of changing curing properties of the cured product. Concrete examples of the curing accelerator (D) include phosphorous-containing curing accelerators such as organic phosphine, a tetra-substituted phosphonium compound, a phosphobetaine compound, an adduct of a phosphine compound and a quinone compound, an adduct of a phosphonium compound and a silane compound and the like; and compounds such as 1,8-diazabicyclo(5,4,0)undecene-7, benzyldimethylamine, 2-methylimidazole and the like. Among these, with the use of the phosphorous-containing curing accelerator, preferable curability may be obtained. From the viewpoint of a balance between the flowability and curability, more preferably used is at least one kind of compound selected from the group consisting of a tetra-substituted phosphonium compound, a phosphobetaine compound, an adduct of a phosphine compound and a quinone compound, and an adduct of a phosphonium compound and a silane compound. When the flowability is considered important, a tetra-substituted phosphonium compound is particularly preferable. When low elastic modulus during heating of the cured product of the resin composition for encapsulating a semiconductor is considered important, a phosphobetaine compound and an adduct of a phosphine compound and a quinone compound are particularly preferable. When latent curability is considered important, an adduct of a phosphonium compound and a silane compound is particularly preferable.

Examples of the organic phosphine which may be used for the resin composition for encapsulating a semiconductor of the present invention include primary phosphines such as ethylphosphine, phenylphosphine and the like; secondary phosphines such as dimethylphosphine, diphenylphosphine and the like; and tertiary phosphines such as trimethylphosphine, triethylphosphine, tributylphosphine, triphenylphosphine and the like.

Examples of the tetra-substituted phosphonium compound which may be used for the resin composition for encapsulating a semiconductor of the present invention include compounds represented by the general formula (5),

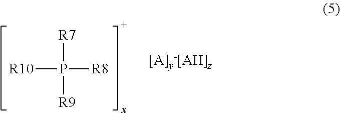

wherein, in the general formula (5), P represents a phosphorus atom; each of R7, R8, R9 and R10 represents an aromatic group or an alkyl group; A represents an anion of an aromatic organic acid having, on the aromatic ring, at least one functional group selected from a hydroxyl group, a carboxyl group and a thiol group; AH represents an aromatic organic acid having, on the aromatic ring, at least one functional group selected from a hydroxyl group, a carboxyl group and a thiol group; y represents an integer of from 1 to 3; z represents an integer of from 0 to 3; and x=y.

The compound represented by the general formula (5) is obtained, for example, in the following manner, but is not restricted thereto. First, tetra-substituted phosphonium halide, an aromatic organic acid and a base are uniformly mixed with an organic solvent, to generate an anion of the aromatic organic acid in the solution system. Next, water is added thereto. Thus, the compound represented by the general formula (5) is precipitated. The compound represented by the general formula (5) is preferably a compound in which each of R7, R8, R9 and R10 bonded to a phosphorus atom is a phenyl group; AH is a compound having a hydroxyl group on its aromatic ring, that is, phenols; and A is an anion of the phenols.

Examples of the phosphobetaine compound which may be used for the resin composition for encapsulating a semiconductor of the present invention include compounds represented by the general formula (6),

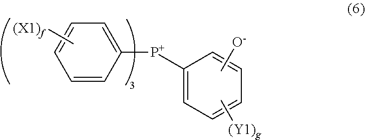

wherein, in the general formula (6), P represents a phosphorus atom; X1 represents an alkyl group having 1 to 3 carbon atoms; Y1 represents a hydroxyl group; f is an integer of from 0 to 5; and g is an integer of from 0 to 4.

The compound represented by the general formula (6) is obtained, for example, in the following manner. First, the compound represented by the general formula (6) is obtained by bringing a tertiary phosphine, that is, a tri-aromatic substituted phosphine into contact with a diazonium salt to substitute the tri-aromatic substituted phosphine for a diazonium group of the diazonium salt. However, the process is not limited thereto.

Examples of the adduct of a phosphine compound and a quinone compound which may be used for the resin composition for encapsulating a semiconductor of the present invention include compounds represented by the general formula (7),

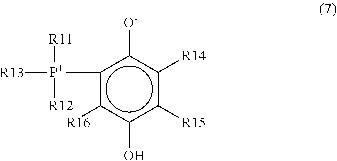

wherein, in the general formula (7), P represents a phosphorus atom; each of R11, R12 and R13 represents an alkyl group having 1 to 12 carbon atoms or an aryl group having 6 to 12 carbon atoms, and may be the same or different from each other; and each of R14, R15 and R16 represents a hydrogen atom or a hydrocarbon group having 1 to 12 carbon atoms, and may be the same or different from each other, or R14 and R15 may be bonded so as to form a ring structure.

Examples of the phosphine compound used for the adduct of a phosphine compound and a quinone compound include unsubstituted aromatic ring-containing phosphines such as triphenylphosphine, tris(alkylphenyl)phosphine, tris(alkoxyphenyl)phosphine, trinaphthylphosphine, tris(benzyl)phosphine and the like; and phosphines containing an aromatic ring substituted with an alkyl group or an alkoxy group. Examples of the alkyl group and the alkoxy group include alkyl groups having 1 to 6 carbon atoms and alkoxy groups having 1 to 6 carbon atoms. From the viewpoint of easy availability, preferably used is triphenylphosphine.

Examples of the quinone compound used for the adduct of a phosphine compound and a quinone compound include o-benzoquinone, p-benzoquinone, anthraquinones and the like. Among these, p-benzoquinone is preferable from the viewpoint of storage stability.

In a method for producing an adduct of a phosphine compound and a quinone compound, an organic tertiary phosphine is brought into contact with a benzoquinone in a solvent that can dissolve both the organic tertiary phosphine and the benzoquinone and mixed to produce an adduct thereof. Any solvent can be used as long as the solubility of the adduct to the solvent is low. Examples of the solvent include, but are not limited to, ketones such as acetone and methyl ethyl ketone.

The compound represented by the general formula (7) is preferably a compound in which each of R11, R12 and R13 bonded to a phosphorus atom is a phenyl group; and each of R14, R15 and R16 is a hydrogen atom, that is, a compound produced by adding 1,4-benzoquinone and triphenylphosphine, because the elastic modulus during heating of the cured product of the resin composition for encapsulating a semiconductor can be maintained to low levels.

Examples of the adduct of a phosphonium compound and a silane compound which may be used for the resin composition for encapsulating a semiconductor of the present invention include compounds represented by the general formula (8),

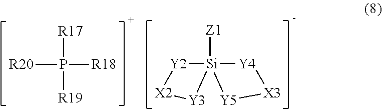

wherein, in the general formula (8), P represents a phosphorus atom; Si represents a silicon atom; each of R17, R18, R19 and R20 represents an organic group having an aromatic ring or a heterocyclic ring, or an aliphatic group, and may be the same or different from each other; X2 is an organic group that bonds group Y2 to group Y3; X3 is an organic group that bonds group Y4 to group Y5; Y2 and Y3 each represent a group formed when a proton-donating group releases a proton, and group Y2 and group Y3 in the same molecule are linked with the silicon atom to form a chelate structure; Y4 and Y5 each represent a group formed when a proton-donating group releases a proton, and group Y4 and group Y5 in the same molecule are linked with the silicon atom to form a chelate structure; X2 and X3 may be the same or different from each other; Y2, Y3, Y4 and Y5 may be the same or different from each other; and Z1 is an organic group having an aromatic ring or a heterocyclic ring, or an aliphatic group.

Examples of R17, R18, R19 and R20 in the general formula (8) include a phenyl group, a methylphenyl group, a methoxyphenyl group, a hydroxyphenyl group, a naphthyl group, a hydroxynaphthyl group, a benzyl group, a methyl group, an ethyl group, an n-butyl group, an n-octyl group, a cyclohexyl group and the like. Among these, more preferably used are aromatic groups having a substituent and unsubstituted aromatic groups such as a phenyl group, a methylphenyl group, a methoxyphenyl group, a hydroxyphenyl group, a hydroxynaphthyl group and the like.

Meanwhile, in the general formula (8), X2 is an organic group that bonds group Y2 to group Y3. Similarly, X3 is an organic group that bonds group Y4 to group Y5. Each of Y2 and Y3 is a group formed when a proton-donating group releases a proton, and group Y2 and group Y3 in the same molecule are bonded to the silicon atom to form a chelate structure. Similarly, each of Y4 and Y5 is a group formed when a proton-donating group releases a proton, and group Y4 and group Y5 in the same molecule are bonded to the silicon atom to form a chelate structure. Groups X2 and X3 may be the same or different from each other, and groups Y2, Y3, Y4 and Y5 may be the same or different from each other. Each of the group represented by —Y2-X2-Y3- and the group represented by Y4-X3-Y5- in the general formula (8) is a group formed when a proton donor releases two protons. Examples of the proton donor include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-propanediol, glycerin and the like. Among these, more preferably used are catechol, 1,2-dihydroxynaphthalene and 2,3-dihydroxynaphthalene.

In the general formula (8), Z1 is an organic group having an aromatic ring or a heterocyclic ring, or an aliphatic group. Specific examples of Z1 include aliphatic hydrocarbon groups such as a methyl group, an ethyl group, a propyl group, a butyl group, a hexyl group, an octyl group and the like; aromatic hydrocarbon groups such as a phenyl group, a benzyl group, a naphthyl group, a biphenyl group and the like; and organic groups having a reactive substituent such as a glycidyloxypropyl group, a mercaptopropyl group, an aminopropyl group, a vinyl group and the like. Among these, more preferably used are a methyl group, an ethyl group, a phenyl group, a naphthyl group and a biphenyl group in view of improvement in thermal stability of the general formula (8).

In a method for producing an adduct of a phosphonium compound and a silane compound, a silane compound such as phenyltrimethoxysilane and a proton donor such as 2,3-dihydroxynaphthalene are added to methanol in a flask and dissolved. Next, a sodium methoxide-methanol solution is added dropwise thereto under stirring at room temperature. Further, a solution prepared by dissolving a tetra-substituted phosphonium halide such as tetraphenyl phosphonium bromide in methanol in advance is added dropwise to the resulting reaction product under stirring at room temperature to precipitate crystals. The precipitated crystals are filtered, washed with water, and then dried in vacuum. Thus, an adduct of a phosphonium compound and a silane compound is produced. However, the method is not limited to this.

The mixing ratio of the curing accelerator (D) which may be used for the resin composition for encapsulating a semiconductor of the present invention is preferably equal to or more than 0.1% by mass and equal to or less than 1% by mass, based on the total resin composition. When the mixing amount of the curing accelerator (D) is within the above range, sufficient curability and flowability may be achieved.

The resin composition for encapsulating a semiconductor of the present invention further contains a compound (E) in which a hydroxyl group is bonded to each of two or more adjacent carbon atoms constituting an aromatic ring (hereinafter referred to as the compound (E)). With the use of the compound (E), even when a phosphorus-containing curing accelerator without having latency is used as the curing accelerator (D) for accelerating a crosslinking reaction between the phenol resin and the epoxy resin, the reaction of the resin composition during the melt-kneading may be suppressed, so that a stable resin composition for encapsulating a semiconductor can be obtained. Furthermore, the compound (E) also has an effect of decreasing the melt viscosity of the resin composition for encapsulating a semiconductor and increasing flowability. Examples of the compound (E) include a monocyclic compound represented by the following general formula (9), a polycyclic compound represented by the following general formula (10) and the like, and these compounds may have a substituent other than the hydroxyl group,

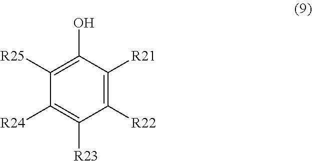

wherein, in the general formula (9), any one of R21 and R25 is a hydroxyl group; when one of R21 and R25 is a hydroxyl group, the other is a hydrogen atom, a hydroxyl group or a substituent other than the hydroxyl group; and each of R22, R23 and R24 is a hydrogen atom, a hydroxyl group or a substituent other than the hydroxyl group,

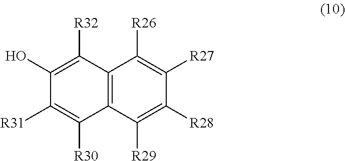

wherein, in the general formula (10), any one of R31 and R32 is a hydroxyl group; when one of R31 and R32 is a hydroxyl group, the other is a hydrogen atom, a hydroxyl group or a substituent other than the hydroxyl group; and each of R26, R27, R28, R29 and R30 is a hydrogen atom, a hydroxyl group or a substituent other than the hydroxyl group.

Examples of the monocyclic compound represented by the general formula (9) include catechol, pyrogallol, gallic acid, gallic acid esters and their derivatives. Examples of the polycyclic compound represented by the general formula (10) include 1,2-dihydroxynaphthalene, 2,3-dihydroxynaphthalene and their derivatives. Among these, preferably used is a compound in which a hydroxyl group is bonded to each of two adjacent carbon atoms constituting an aromatic ring from the viewpoint of easy control of flowability and curability. Furthermore, in consideration of volatilization in a step of kneading, more preferably used is a compound having, as a mother nucleus, a naphthalene ring which has low volatility and high weighing stability. In this case, the compound (E) may be specifically, for example, a compound having a naphthalene ring such as 1,2-dihydroxynaphthalene, 2,3-dihydroxynaphthalene and their derivatives. These compounds (E) may be used singly or may be used in combination of two or more kinds.

The mixing amount of compound (E) is preferably equal to or more than 0.01% by mass and equal to or less than 1% by mass, more preferably equal to or more than 0.03% by mass and equal to or less than 0.8% by mass, and particularly preferably equal to or more than 0.05% by mass and equal to or less than 0.5% by mass, in the total amount of the resin composition for encapsulating a semiconductor. When the lower limit of the mixing amount of the compound (E) is within the above range, the effect of improving sufficient low viscosity and flowability of the resin composition for encapsulating a semiconductor may be achieved. Meanwhile, when the upper limit of the mixing amount of the compound (E) is within the above range, there is less possibility of deteriorating curability and continuous molding property of the resin composition for encapsulating a semiconductor or causing cracks at a solder reflow temperature.

In the resin composition for encapsulating a semiconductor of the present invention, for the purpose of improving adhesion between the epoxy resin and the inorganic filler, a coupling agent (F) may be further added. As the coupling agent (F), preferably used is a silane coupling agent. The silane coupling agent is not particularly limited, and examples thereof include epoxysilane, aminosilane, ureidosilane, mercaptosilane and the like, and it may be any one which can be reacted or acts between an epoxy resin and an inorganic filler to improve the interfacial strength between the epoxy resin and the inorganic filler. Furthermore, when the coupling agent (F) may be used together with the aforementioned compound (E), the coupling agent enhances the effect that the compound (E) reduces the melt viscosity of the resin composition and improves flowability.

Examples of the epoxysilane include γ-glycidoxypropyltriethoxysilane, γ-glycidoxypropyltrimethoxysilane, γ-glycidoxypropylmethyldimethoxysilane, β-(3,4-epoxycyclohexyl)ethyltrimethoxysilane and the like.

Examples of the aminosilane include γ-aminopropyltriethoxysilane, γ-aminopropyltrimethoxysilane, N-β(aminoethyl)γ-aminopropyltrimethoxysilane, N-β(aminoethyl)γ-aminopropylmethyldimethoxysilane, N-phenylγ-aminopropyltriethoxysilane, N-phenylγ-aminopropyltrimethoxysilane, N-β(aminoethyl)γ-aminopropyltriethoxysilane, N-6-(aminohexyl)-3-aminopropyltrimethoxysilane, N-(3-(trimethoxysilylpropyl)-1,3-benzenedimethanane and the like. A latent aminosilane coupling agent protected by reacting a primary amino moiety of aminosilane with ketone or aldehyde may be used. Examples of the ureidosilane include γ-ureidopropyltriethoxysilane, hexamethyldisilazane and the like. Examples of the mercaptosilane include a silane coupling agent exhibiting the same function as the mercaptosilane coupling agent by thermal decomposition, such as bis(3-triethoxysilylpropyl)tetrasulfide and bis(3-triethoxysilylpropyl)disulfide, and the like, in addition to γ-mercaptopropyltrimethoxysilane and 3-mercaptopropylmethyldimethoxysilane. These silane coupling agents may also be added after hydrolyzing in advance. These silane coupling agents may be used singly or may be used in combination of two or more kinds.

The lower limit of the mixing ratio of the coupling agent (F) which may be used for the resin composition for encapsulating a semiconductor of the present invention is preferably equal to or more than 0.01% by mass, more preferably equal to or more than 0.05% by mass and particularly preferably equal to or more than 0.1% by mass, in the total amount of the resin composition. When the lower limit of the mixing ratio of the coupling agent (F) is within the above range, excellent solder resistance in a semiconductor device may be achieved without lowering the interfacial strength between the epoxy resin and the inorganic filler. Meanwhile, the upper limit of the coupling agent (F) is preferably equal to or less than 1.0% by mass, more preferably equal to or less than 0.8% by mass and particularly preferably equal to or less than 0.6% by mass, in the total amount of the resin composition. When the upper limit of the mixing ratio of the coupling agent (F) is within the above range, excellent solder resistance in a semiconductor device may be achieved without lowering the interfacial strength between the epoxy resin and the inorganic filler. When the mixing ratio of the coupling agent (F) is within the above range, excellent solder resistance in a semiconductor device may be achieved without increasing water absorption property of the cured product of the resin composition.

In the resin composition for encapsulating a semiconductor of the present invention, an inorganic flame retardant (G) may be further added for the purpose of enhancing flame resistance. The inorganic flame retardant (G) is not particularly limited, and examples thereof include metal hydroxides such as aluminum hydroxide, magnesium hydroxide and the like, zinc borate, zinc molybdate, antimony trioxide and the like. These inorganic flame retardants (G) may be used singly or may be used in combination of two or more kinds.

The mixing ratio of the inorganic flame retardant (G) which may be used for the resin composition for encapsulating a semiconductor of the present invention is preferably equal to or more than 0.5% by mass and equal to or less than 6.0% by mass in the total amount of the resin composition. When the mixing ratio of the inorganic flame retardant (G) is within the above range, curing for enhancing flame resistance may be achieved without damaging curability and properties.

The resin composition for encapsulating a semiconductor of the present invention, in addition to the aforementioned components, may contain the following additives, as necessary. Examples of the additive include coloring agents such as carbon black, bengala, titanium oxide and the like; mold releasing agents, for example, a natural wax such as a carnauba wax or the like, a synthetic wax such as a polyethylene wax or the like, higher fatty acids and metal salts thereof such as stearic acid, zinc stearate or the like, and paraffin; low-stress additives such as silicon oil, silicon rubber and the like; inorganic ion-exchangers such as bismuth oxide hydrate and the like; and inorganic flame retardants such as phosphate ester, phosphazene and the like.

The resin composition for encapsulating a semiconductor of the present invention is prepared by homogeneously mixing the phenol resin (A), the epoxy resin (B), the inorganic filler (C) and the above-stated other additives at normal temperature using a mixer or the like.

Thereafter, the homogenous mixture is melt-kneaded using a kneading machine such as a hot roll, a kneader or an extruder, and then cooled and pulverized the mixture, as necessary, whereby dispersibility and flowability may be adjusted to desired levels.

Next, the semiconductor device of the present invention will be described. In a method for producing a semiconductor device using the resin composition for encapsulating a semiconductor of the present invention, for example, the resin composition for encapsulating a semiconductor may be molded by a molding method such as transfer molding, compression molding, injection molding or the like and cured, after a lead frame or a circuit board on which a semiconductor element is mounted is placed in a mold cavity, whereby the semiconductor element is encapsulated.

Examples of the semiconductor element to be encapsulated include integrated circuits, large scale integrated circuits, transistors, thyristors, diodes, solid-state image sensing devices and the like, but are not restricted thereto.

Examples of the shape of the semiconductor device to be obtained include a dual in-line package (DIP), a plastic leaded chip carrier (PLCC), a quad flat package (QFP), a low-profile quad flat package (LQFP), a small outline package (SOP), a small outline J-leaded package (SOJ), a thin small outline package (TSOP), a thin quad flat package (TQFP), a tape carrier package (TCP), a ball grid array (BGA), a chip size package (CSP) and the like, but are not restricted thereto.

The semiconductor device obtained by encapsulating a semiconductor element by a molding method such as transfer molding or the like using the resin composition for encapsulating a semiconductor is mounted on any electronic devices without curing or after completely curing the resin composition at a temperature of about 80 to 200 degrees centigrade over a period of about 10 minutes to 10 hours.

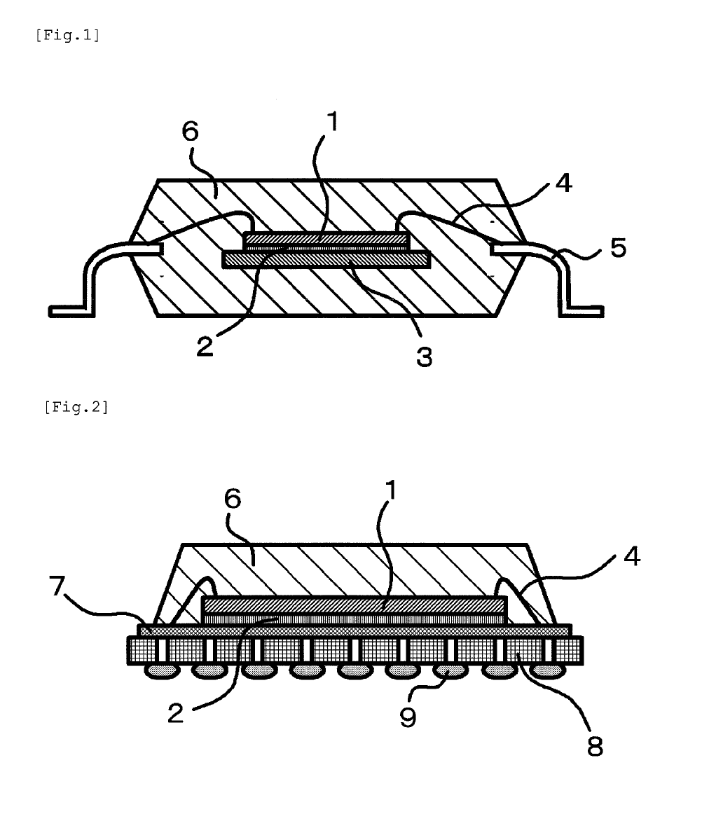

FIG. 1 is a view illustrating a cross-section structure of an example of a semiconductor device using the resin composition for encapsulating a semiconductor according to the present invention. A semiconductor element 1 is fixed on a die pad 3 via a cured die bond material 2. An electrode pad of the semiconductor element 1 and a lead frame 5 are connected by means of a bonding wire 4. The semiconductor element 1 is encapsulated with a cured product 6 of the resin composition for encapsulating a semiconductor.

FIG. 2 is a view illustrating a cross-section structure of an example of a one-side encapsulated semiconductor device using the resin composition for encapsulating a semiconductor according to the present invention. A semiconductor element 1 is fixed on a surface of a substrate 8 through a cured die bond material 2 on a solder resist 7 of a laminate where a layer of the solder resist is formed. In order for electric conduction between the semiconductor element 1 and the substrate 8, the solder resist 7 on the electrode pad is eliminated by a developing method such that the electrode pad is exposed. Accordingly, the semiconductor device in FIG. 2 is designed to connect the electrode pad of the semiconductor element 1 and the electrode pad on the substrate 8 by means of a bonding wire 4. The encapsulating resin composition is used for encapsulating a semiconductor device and a cured product 6 is formed, whereby a semiconductor device in which only one surface of the substrate 8 with the semiconductor element 1 mounted thereon is encapsulated can be obtained. The electrode pad on the substrate 8 is internally connected to a solder ball 9 provided on the non-encapsulated surface of the substrate 8.

### EXAMPLES

The present invention is now illustrated in detail below with reference to Examples. However, the present invention is not restricted to these Examples. In the following Examples, the mixing amount of each component is represented by “parts by mass” unless otherwise particularly noted.

The following phenol resins 1 to 6 were used for the curing agent.

Among these, phenol resins 1 and 2 correspond to the phenol resin (A).

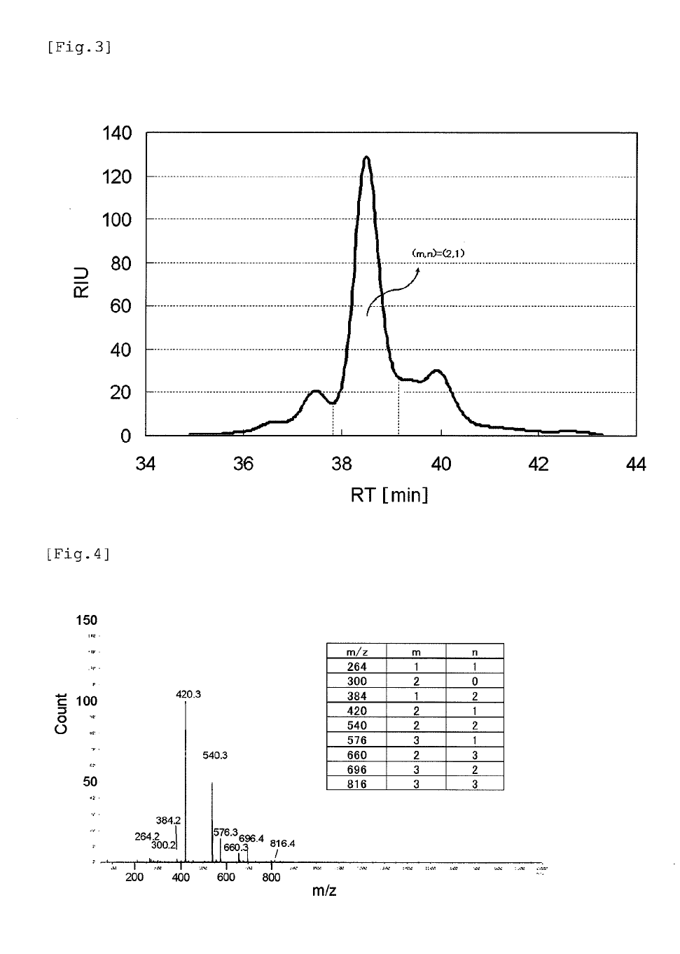

Phenol resin 1: 108 g (1 mole) of o-cresol (a product of Tokyo Chemical Industry, Co., Ltd.) was fed into a flask equipped with a thermometer, a stirrer and a condenser, which was completely dissolved under a nitrogen atmosphere while maintaining a temperature at 30 degrees centigrade. After dissolution, 134 g of a 30% aqueous sodium hydroxide solution (sodium hydroxide: 1 mole) was added dropwise to the reaction solution. Thereafter, the reaction temperature was further kept at 30 degrees centigrade for 1 hour. Next, 60 g (2 moles) of para-formaldehyde (a product of Tokyo Chemical Industry, Co., Ltd.) was added thereto, and the mixture was reacted at a reaction temperature of 30 degrees centigrade for 1 hour, and further reacted at a reaction temperature of 45 degrees centigrade for 2 hours, whereby a cresol methylol compound was obtained. Thereafter, this reaction solution was cooled to 20 degrees centigrade and 91.3 g of concentrated sulfuric acid was added dropwise thereto while paying attention to generation of heat, whereby the reaction solution was neutralized. Next, 250 ml of methanol and 864 g (6 moles) of α-naphthol (a product of Tokyo Chemical Industry, Co., Ltd.) were added to this reaction solution. After addition, 10 g of concentrated hydrochloric acid (0.1 mole as the hydrochloric acid moisture component) was immediately added dropwise at a reaction temperature set to 50 degrees centigrade. After dropwise addition, the mixture was reacted at a reaction temperature set to 60 degrees centigrade for 2 hours, and further reacted by heating at 80 degrees centigrade for 1 hour. After completion of the reaction, in order to remove an acid catalyst, the mixture was dissolved in 1,000 ml of methyl isobutyl ketone and repeatedly washed with water. The methyl isobutyl ketone phase back to neutral by repeatedly washing with water was heated and distilled under reduced pressure to remove methyl isobutyl ketone and unreacted α-naphthol, whereby a phenol resin 1 (softening point: 107 degrees centigrade, hydroxyl equivalent: 140 g/eq, ICI viscosity at 150 degrees centigrade: 3.60 dPa·sec, (m,n)=(2,1) component: 57% by area) was obtained. A GPC chart is illustrated in FIG. 3, while the FD-MS results are shown in FIG. 4.

Phenol resin 2: A phenol resin 2 (softening point: 105 degrees centigrade, hydroxyl equivalent: 138 g/eq, ICI viscosity at 150 degrees centigrade: 3.50 dPa·sec, (m,n)=(2,1) component: 59% by area) was obtained in the same manner as in Synthesis Example 1, except that 864 g (6 moles) of β-naphthol (a product of Tokyo Chemical Industry, Co., Ltd.) was used instead of 864 g (6 moles) of α-naphthol.

Phenol resin 3: A phenol resin 3 (softening point: 106 degrees centigrade, hydroxyl equivalent: 139 g/eq, ICI viscosity at 150 degrees centigrade: 3.60 dPa·sec, (m,n)=(2,1) component: 58% by area) was obtained in the same manner as in Synthesis Example 1, except that 108 g (1 mole) of p-cresol (a product of Tokyo Chemical Industry, Co., Ltd.) was used instead of 108 g (1 mole) of o-cresol.

Phenol resin 4: A phenol resin 4 (softening point: 105 degrees centigrade, hydroxyl equivalent: 139 g/eq, ICI viscosity at 150 degrees centigrade: 3.50 dPa·sec, (m,n)=(2,1) component: 59% by area) was obtained in the same manner as in Synthesis Example 1, except that 108 g (1 mole) of p-cresol (a product of Tokyo Chemical Industry, Co., Ltd.) was used instead of 108 g (1 mole) of o-cresol and 864 g (6 moles) of β-naphthol (a product of Tokyo Chemical Industry, Co., Ltd.) was used instead of 864 g (6 moles) of α-naphthol.

Phenol resin 5: A co-condensation type phenol resin consisting of p-cresol and α-naphthol (KAYAHARD NHN, commercially available from Nippon Kayaku Co., Ltd., hydroxyl equivalent: 143 g/eq, softening point: 109 degrees centigrade, ICI viscosity at 150 degrees centigrade: 23.0 dPa·sec, (m,n)=(2,1) component: 54% by area) represented by the formula (11),

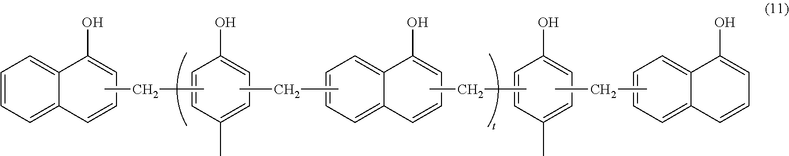

wherein, in the formula (11), t is an integer of from 0 to 10.

Phenol resin 6: A triphenylmethane type phenol resin (MEH-7500, commercially available from Meiwa Plastic Industries, Ltd., hydroxyl equivalent: 97, softening point: 110 degrees centigrade, ICI viscosity at 150 degrees centigrade: 5.8 dPa·sec).

GPC measurement of the phenol resin 1 was carried out under the following conditions. 6 ml of tetrahydrofuran (THF) as a solvent was added to 20 mg of a sample of the phenol resin 1, and the resulting mixture was fully dissolved and subjected to the GPC measurement. As the GPC system, there was used one in which a module W2695 commercially available from Waters Corporation, TSK GUARDCOLUMN HHR-L (a guard column, diameter: 6.0 mm, tube length: 40 mm) commercially available from Tosoh Corporation, two of TSK-GEL GMHHR-L (a polystyrene gel column, diameter: 7.8 mm, tube length: 30 mm) commercially available from Tosoh Corporation and a differential refractive index (R1) detector W2414 commercially available from Waters Corporation were connected in series. The flow rate of the pump was 0.5 ml/min, the internal temperature of the column and differential refractometer was set to 40 degrees centigrade, and a measurement solution was injected from a 100-μl injector for the measurement.

FD-MS measurement of the phenol resin 1 was carried out under the following conditions. 1 g of dimethyl sulfoxide as a solvent was added to 10 mg of a sample of the phenol resin 1, and the resulting mixture was fully dissolved, coated on the FD emitter, and then subjected to the FD-MS measurement. As an FD-MS system, there was used one in which MS-FD15A commercially available from JEOL Ltd. was connected to an ionization part and MS-700 (model name, a double-focusing mass spectrometry device commercially available from JEOL Ltd.) was connected to a detector to carry out the measurement in the detected mass range (m/z) of 50 to 2,000.

The following epoxy resins 1 to 4 were used for the epoxy resin (B).

Epoxy resin 1: A triphenylmethane type epoxy resin (E-1032H60, commercially available from Japan Epoxy Resin Co., Ltd., epoxy equivalent: 171 g/eq, softening point: 59 degrees centigrade, ICI viscosity at 150 degrees centigrade: 1.3 dPa·sec)

Epoxy resin 2: A mixture of a triphenylmethane type epoxy resin and a biphenyl type epoxy resin (YL6677, commercially available from Japan Epoxy Resin Co., Ltd., epoxy equivalent: 163 g/eq, softening point: 59 degrees centigrade, ICI viscosity at 150 degrees centigrade: 0.13 dPa·sec)

Epoxy resin 3: A naphthol type epoxy resin (HP-4770, commercially available from DIC Corporation, epoxy equivalent: 205 g/eq, softening point: 72 degrees centigrade, ICI viscosity at 150 degrees centigrade: 0.90 dPa·sec)

Epoxy resin 4: A dihydroanthracene type epoxy resin (YX8800, commercially available from Japan Epoxy Resin Co., Ltd., epoxy equivalent: 181 g/eq, softening point: 110 degrees centigrade, ICI viscosity at 150 degrees centigrade: 0.11 dPa·sec)

Epoxy resin 5: An ortho-cresol novolac type epoxy resin (N660, commercially available from DIC Corporation, epoxy equivalent: 210 g/eq, softening point: 62 degrees centigrade, ICI viscosity at 150 degrees centigrade: 2.34 dPa·sec)

Epoxy resin 6: A biphenyl type epoxy resin (YX4000K, commercially available from Japan Epoxy Resin Co., Ltd., epoxy equivalent: 185 g/eq, softening point: 107 degrees centigrade, ICI viscosity at 150 degrees centigrade: 0.11 dPa·sec)

As the inorganic filler (C), a blend (an inorganic filler 1) of 87.7% by mass of fused spherical silica, FB560 (commercially available from Denki Kagaku Kogyo Kabushiki Kaisha, average particle diameter: 30 μm), 5.7% by mass of synthesized spherical silica, SO—C2 (commercially available from Admatechs Co., Ltd., average particle diameter: 0.5 μm) and 6.6% by mass of synthesized spherical silica, SO—C5 (commercially available from Admatechs Co., Ltd., average particle diameter: 30 μm) was used.

The following curing accelerators 1 and 2 were used for the curing accelerator (D).

Curing accelerator 1: A curing accelerator represented by the following formula (12),

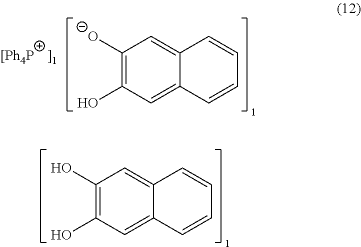

Curing accelerator 2: A curing accelerator represented by the following formula (13),

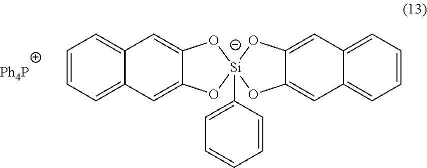

The following silane coupling agents 1 to 3 were used for the silane coupling agent (F).

Silane coupling agent 1: γ-mercaptopropyltrimethoxysilane (KBM-803, commercially available from Shin-Etsu Chemical Co., Ltd.)

Silane coupling agent 2: γ-glycidoxypropyltrimethoxysilane (KBM-403, commercially available from Shin-Etsu Chemical Co., Ltd.)

Silane coupling agent 3: N-phenyl-3-aminopropyltrimethoxysilane (KBM-573, commercially available from Shin-Etsu Chemical Co., Ltd.)

Aluminum hydroxide (CL-310, commercially available from Sumitomo Bakelite Co., Ltd.) was used for the inorganic flame retardant (G).

Carbon black (MA600, commercially available from Mitsubishi Chemical Corporation) was used for the coloring agent.

Carnauba wax (Nikko Carnauba, commercially available from Fine Products Co., Ltd., melting point: 83 degrees centigrade) was used for the mold releasing agent.

### Example 1

The following components were mixed at normal temperature using a mixer, and then melt-kneaded through a hot roll at 80 to 100 degrees centigrade. Thereafter, the resultant was cooled and then pulverized, whereby a resin composition for encapsulating a semiconductor was obtained.

| | | |
|---|---|---|
| Phenol resin 2 | 5.43 | parts by mass |
| Epoxy resin 1 | 7.07 | parts by mass |
| Inorganic filler 1 | 86.5 | parts by mass |
| Curing accelerator 1 | 0.4 | parts by mass |
| Silane coupling agent 1 | 0.1 | part by mass |
| Silane coupling agent 2 | 0.05 | parts by mass |
| Silane coupling agent 3 | 0.05 | parts by mass |
| Carbon black | 0.3 | parts by mass |
| Carnauba wax | 0.1 | part by mass |

The obtained resin composition for encapsulating a semiconductor was evaluated with respect to the following items. The evaluation results are shown in Tables 1 and 2.

Spiral flow: The resin composition for encapsulating a semiconductor obtained in the above was injected into a mold for the measurement of spiral flow in accordance with EMMI-1-66 under the conditions of a mold temperature of 175 degrees centigrade, an injection pressure of 6.9 MPa and a pressure application time of 120 seconds using a low pressure transfer molding machine (KTS-15, commercially available from Kohtaki Precision Machine Co., Ltd.), and the flow length was measured. The spiral flow is a parameter of flowability, and a larger value of the spiral flow means better flowability. The spiral flow is given in units of centimeters (cm). The resin composition for encapsulating a semiconductor obtained in Example 1 exhibited high flowability, that is, 90 cm.

Wire sweep ratio: A silicon chip or the like was encapsulated by the epoxy resin composition and molding was performed under the conditions of a mold temperature of 175 degrees centigrade, an injection pressure of 9.8 MPa and a curing time of 70 seconds using a low pressure automatic transfer molding machine (GP-ELF, commercially available from Dai-ichi Seiko Co., Ltd.) to produce a 160 pin LQFP package (pre-plating frame: gold plated to a nickel/palladium alloy, package outer size: 24 mm×24 mm×1.4 mm (thickness), pad size: 8.5 mm×8.5 mm, chip size: 7.4 mm×7.4 mm×350 μm (thickness)). The resulting 160 pin LQFP package was observed with a soft X-ray fluoroscope (PRO-TEST-100, commercially available from Softex Corporation), and the ratio of (sweep amount)/(wire length) was determined as the sweep ratio of the wire. The sweep ratio is given in units of %. The resin composition for encapsulating a semiconductor obtained in Example 1 exhibited excellent wire sweep ratio, that is, 6%.

Flame resistance: The resin composition for encapsulating a semiconductor was injected and molding was performed under the conditions of a mold temperature of 175 degrees centigrade, an injection time of 15 seconds, a curing time of 120 seconds and an injection pressure of 9.8 MPa using a low pressure transfer molding machine (KTS-30, commercially available from Kohtaki Precision Machine Co., Ltd.) to prepare a flame-resistant test piece having a thickness of 3.2 mm, following by heating at 175 degrees centigrade for 4 hours. The prepared test piece was subjected to a flame resistance test in accordance with a standard specified in the UL-94 vertical method to evaluate flame resistance. Fmax, EF and rank of flame resistance after determination were shown in Tables. The resin composition for encapsulating a semiconductor obtained in Example 1 exhibited excellent flame resistance, that is, Fmax of 4 seconds, ΣF of 9 seconds and rank of flame resistance of V-0.

Glass transition point: A test piece having a length of 15 mm, a width of 4 mm and a thickness of 3 mm was molded under the conditions of a mold temperature of 175 degrees centigrade, a pressure of 9.8 MPa and a curing time of 120 seconds using a low pressure transfer molding machine (TEP-50-30, commercially available from Fujiwa Seiki Co., Ltd.). The test piece was subjected to post-curing treatment and heated at 175 degrees centigrade for 4 hours. Then, a temperature in which elongation percentage of the test piece was abruptly changed by heating at a temperature elevation rate of 5 degrees centigrade/min. using a thermal dilatometer (TMA-120, commercially available from Seiko Instruments Inc.) was measured as the glass transition point. The unit is degrees centigrade. Furthermore, the test piece may also be a test piece having about a length of 5 mm, a width of 4 mm and a thickness of 2 mm cut from the 80 pin QFP prepared in the solder resistance test to be described below. The resin composition for encapsulating a semiconductor obtained in Example 1 exhibited a glass transition temperature of 164 degrees centigrade which was a suitable glass transition temperature in order to obtain suitable elastic modulus during heating.

Boiling water absorption ratio: A disk-like test piece having a diameter of 50 mm and a thickness of 3 mm was molded under the conditions of a mold temperature of 175 degrees centigrade, an injection pressure of 9.8 MPa and a curing time of 120 seconds using a low pressure transfer molding machine (KTS-30, commercially available from Kohtaki Precision Machine Co., Ltd.), and heated at 175 degrees centigrade for 4 hours. The mass change of the test piece before the hygroscopic treatment and after the boiling treatment in pure water for 24 hours was measured, and the water absorption ratio of the test piece was expressed as a percentage. The unit is % by mass. The resin composition for encapsulating a semiconductor obtained in Example 1 exhibited low water absorption property, that is, 0.129% by mass.

Continuous molding property: 7.5 g (mass) of the resin composition for encapsulating a semiconductor obtained in the above was placed in a tablet having a size of φ16 mm using a rotary tablet machine, and tableted under a tablet pressure of 600 Pa to obtain a tablet. A tablet supply magazine with the obtained tablet placed therein was set to the inside of the molding machine. Using a low pressure automatic transfer molding machine (SY-COMP, commercially available from Scinex Corporation), molding of up to 300 shots of a semiconductor device of 208 pin QFP (a Cu lead frame, package outer size: 28 mm×28 mm×3.2 mm (thickness), pad size: 15.5 mm×15.5 mm, chip size: 15.0 mm×15.0 mm×0.35 mm (thickness)) obtained by encapsulating a silicon chip or the like with the tablet of the resin composition for encapsulating a semiconductor was conducted in a continuous manner under the conditions of a mold temperature of 175 degrees centigrade, an injection pressure of 9.8 MPa and a curing time of 60 seconds. In this case, the molding state (presence or absence of insufficient filling) of the semiconductor device was confirmed per every 25 shots. o marks were indicated when 300 shots or more for continuous molding were confirmed, Δ marks were indicated when equal to or more than 150 shots and less than 300 shots were confirmed, and x marks were indicated when less than 150 shots were confirmed. The resin composition for encapsulating a semiconductor obtained in Example 1 exhibited excellent continuous molding property, that is, equal to or more than 300 shots.

Solder resistance test 1: The resin composition for encapsulating a semiconductor was injected to encapsulate a lead frame or the like on which a semiconductor element (a silicon chip) was mounted and molding was performed under the conditions of a mold temperature of 180 degrees centigrade, an injection pressure of 7.4 MPa and a curing time of 120 seconds using a low pressure transfer molding machine (GP-ELF, commercially available from Dai-ichi Seiko Co., Ltd.). Thus, a semiconductor device composed of 80pQFP (Quad Flat Package, a Cu lead frame, size: 14×20 mm×2.00 mm (thickness), semiconductor element size: 7×7 mm×0.35 mm (thickness), the semiconductor element being bonded to an inner lead part of the lead frame using a gold wire having a diameter of 25 μm) was prepared. The prepared six semiconductor devices heat-treated at 175 degrees centigrade for 4 hours were treated at 30 degrees centigrade and a relative humidity of 60% for 192 hours, and an IR reflow process (at 260 degrees centigrade in accordance with the condition of JEDEC Level 3) was then performed. The presence or absence of detachment and cracks inside the semiconductor devices was observed with a scanning acoustic tomograph (mi-scope 10, commercially available from Hitachi Kenki Fine Tech Co., Ltd.). Semiconductor devices in which at least one of detachment and a crack was caused were evaluated as defective. When the number of defective semiconductor devices was n, the result was shown as n/6. The semiconductor device obtained in Example 1 exhibited excellent reliability, that is, 0/6.

Solder resistance test 2: The test was carried out in the same manner as in the solder resistance test 1, except that the six semiconductor devices heat-treated at 175 degrees centigrade for 4 hours in the above solder resistance test 1 were treated at a temperature of 30 degrees centigrade and a relative humidity of 60% for 96 hours. The semiconductor device obtained in Example 1 exhibited excellent reliability, that is, 0/6.

o marks were indicated when a package was not defective through both solder resistance tests 1 and 2, while x marks were indicated when a package was defective through both or one of solder resistance tests 1 and 2.

High temperature storage life: The resin composition for encapsulating a semiconductor was injected to encapsulate a lead frame or the like on which a semiconductor element (a silicon chip) was mounted and molding was performed under the conditions of a mold temperature of 180 degrees centigrade, an injection pressure of 6.9±0.17 MPa and a period of 90 seconds using a low pressure transfer molding machine (GP-ELF, commercially available from Dai-ichi Seiko Co., Ltd.). Thus, a semiconductor device composed of 16 pin DIP (Dual Inline Package, a 42 alloy lead frame, size: 7 mm×11.5 mm×1.8 mm (thickness), semiconductor element size: 5×9 mm×0.35 mm (thickness), the semiconductor element having an oxide layer having a thickness of 5 μm formed on its surface and further an aluminum wiring pattern having a line and space of 10 μm formed thereon, and an aluminum wiring pad section and a lead frame pad section on the element being bonded by means of a gold wire having a diameter of 25 μm) was prepared. The initial resistances of ten semiconductor devices post-cured by being heat-treated at 175 degrees centigrade for 4 hours were measured, and a high temperature storage treatment was carried out at 185 degrees centigrade for 1,000 hours. When the resistance of a semiconductor device after the high temperature treatment was measured and it was equal to or more than 130% of the initial resistance of the semiconductor device, the semiconductor device was evaluated as defective. o marks were indicated when the number of defective semiconductor devices was 0, while x marks were indicated when the number was 1 to 10. The semiconductor device obtained in Example 1 exhibited excellent reliability, that is, 0/10.

### Examples 2 to 9, Comparative Examples 1 to 8

The resin compositions for encapsulating a semiconductor were produced in the same manner as in Example 1 according to formulations shown in Tables 1 and 2, and evaluated in the same manner as in Example 1. The evaluation results are shown in Tables 1 and 2.

TABLE 1

| | | Example | | | | |
|---|---|---|---|---|---|---|
| | | 1 | 2 | 3 | 4 | 5 |
| (A) | Phenol resin 1 | | | | | 5.45 |
| Component | Phenol resin 2 | 5.43 | 5.58 | 4.88 | 5.26 | |
| Other | Phenol resin 3 | | | | | |
| curing | Phenol resin 4 | | | | | |
| agents | Phenol resin 5 | | | | | |
| | Phenol resin 6 | | | | | |
| (B) | Epoxy resin 1 | 7.07 | | | | 7.05 |
| Component | Epoxy resin 2 | | 6.92 | | | |
| | Epoxy resin 3 | | | 7.62 | | |
| | Epoxy resin 4 | | | | 7.24 | |
| Other epoxy | Epoxy resin 5 | | | | | |
| resins | Epoxy resin 6 | | | | | |
| (C) | Inorganic filler 1 | 86.5 | 86.5 | 86.5 | 86.5 | 86.5 |
| Component | | | | | | |
| (D) | Curing accelerator 1 | 0.4 | 0.4 | 0.4 | 0.4 | 0.4 |
| Component | Curing accelerator 2 | | | | | |
| (F) | Silane coupling agent 1 | 0.1 | 0.1 | 0.1 | 0.1 | 0.1 |
| Component | Silane coupling agent 2 | 0.05 | 0.05 | 0.05 | 0.05 | 0.05 |
| | Silane coupling agent 3 | 0.05 | 0.05 | 0.05 | 0.05 | 0.05 |
| (G) | Aluminum hydroxide | | | | | |
| Component | | | | | | |
| Other | Carbon black | 0.3 | 0.3 | 0.3 | 0.3 | 0.3 |
| additives | Carnauba wax | 0.1 | 0.1 | 0.1 | 0.1 | 0.1 |
| Flowability | Spiral flow [cm] | 90 | 101 | 98 | 112 | 88 |
| | Wire sweep ratio [%] | 6 | 5 | 6 | 5 | 6 |
| Flame | Flame resistance test Fmax | 4 | 4 | 4 | 1 | 3 |
| resistance | [sec] | | | | | |
| | Flame resistance test ΣF | 9 | 13 | 7 | 3 | 8 |
| | [sec] | | | | | |
| | Flame resistance test | V-0 | V-0 | V-0 | V-0 | V-0 |
| | rank of flame resistance | | | | | |
| Heat | Glass transition point Tg | 164 | 155 | 161 | 150 | 165 |
| resistance | [degrees centigrade] | | | | | |
| Water | Boiling water absorption | 0.129 | 0.091 | 0.115 | 0.071 | 0.131 |
| absorption | ratio [% by mass] | | | | | |
| property | | | | | | |
| Continuous | Continuous molding property | ∘ | ∘ | ∘ | ∘ | ∘ |
| molding | | | | | | |
| property | | | | | | |
| Solder | Solder resistance test 1 | 0/6 | 0/6 | 0/6 | 0/6 | 0/6 |
| resistance | [number of defective | | | | | |
| | devices in n = 6] | | | | | |
| | Solder resistance test 2 | 0/6 | 0/6 | 0/6 | 0/6 | 0/6 |
| | [number of defective | | | | | |
| | devices in n = 6] | | | | | |
| | Determination | ∘ | ∘ | ∘ | ∘ | ∘ |
| High | High temperature storage | 0/10 | 0/10 | 0/10 | 0/10 | 0/10 |
| temperature | life (HTSL) | | | | | |
| storage | Determination | ∘ | ∘ | ∘ | ∘ | ∘ |
| life | | | | | | |

| | | Example | | | |
|---|---|---|---|---|---|
| | | 6 | 7 | 8 | 9 |
| (A) | Phenol resin 1 | 4.90 | 5.28 | | |
| Component | Phenol resin 2 | | | 5.43 | 5.43 |
| Other | Phenol resin 3 | | | | |
| curing | Phenol resin 4 | | | | |
| agents | Phenol resin 5 | | | | |
| | Phenol resin 6 | | | | |
| (B) | Epoxy resin 1 | | | 7.07 | 7.07 |
| Component | Epoxy resin 2 | | | | |
| | Epoxy resin 3 | 7.60 | | | |
| | Epoxy resin 4 | | 7.22 | | |
| Other epoxy | Epoxy resin 5 | | | | |
| resins | Epoxy resin 6 | | | | |
| (C) | Inorganic filler 1 | 86.5 | 86.5 | 86.5 | 86.5 |
| Component | | | | | |
| (D) | Curing accelerator 1 | 0.4 | 0.4 | | 0.4 |
| Component | Curing accelerator 2 | | | 0.4 | |
| (F) | Silane coupling agent 1 | 0.1 | 0.1 | 0.1 | 0.1 |
| Component | Silane coupling agent 2 | 0.05 | 0.05 | 0.05 | 0.05 |
| | Silane coupling agent 3 | 0.05 | 0.05 | 0.05 | 0.05 |
| (G) | Aluminum hydroxide | | | | 2.0 |
| Component | | | | | |
| Other | Carbon black | 0.3 | 0.3 | 0.3 | 0.3 |
| additives | Carnauba wax | 0.1 | 0.1 | 0.1 | 0.1 |
| Flowability | Spiral flow [cm] | 94 | 107 | 99 | 89 |
| | Wire sweep ratio [%] | 6 | 5 | 6 | 6 |
| Flame | Flame resistance test Fmax | 3 | 2 | 2 | 1 |
| resistance | [sec] | | | | |
| | Flame resistance test ΣF | 7 | 4 | 6 | 1 |
| | [sec] | | | | |
| | Flame resistance test | V-0 | V-0 | V-0 | V-0 |
| | rank of flame resistance | | | | |
| Heat | Glass transition point Tg | 163 | 153 | 161 | 163 |
| resistance | [degrees centigrade] | | | | |
| Water | Boiling water absorption | 0.111 | 0.073 | 0.121 | 0.133 |
| absorption | ratio [% by mass] | | | | |
| property | | | | | |
| Continuous | Continuous molding property | ∘ | ∘ | ∘ | ∘ |
| molding | | | | | |
| property | | | | | |
| Solder | Solder resistance test 1 | 0/6 | 0/6 | 0/6 | 0/6 |
| resistance | [number of defective devices | | | | |
| | in n = 6] | | | | |
| | Solder resistance test 2 | 0/6 | 0/6 | 0/6 | 0/6 |
| | [number of defective devices | | | | |
| | in n = 6] | | | | |
| | Determination | ∘ | ∘ | ∘ | ∘ |
| High | High temperature storage life | 0/10 | 0/10 | 0/10 | 0/10 |
| temperature | (HTSL) | | | | |
| storage | Determination | ∘ | ∘ | ∘ | ∘ |
| life | | | | | |

TABLE 2

| | | Comparative Example | | | |
|---|---|---|---|---|---|
| | | 1 | 2 | 3 | 4 |
| (A) Component | Phenol resin 1 | | | | |
| | Phenol resin 2 | | | 4.81 | |
| Other curing agents | Phenol resin 3 | 5.45 | | | |
| | Phenol resin 4 | | 5.43 | | 4.81 |
| | Phenol resin 5 | | | | |
| | Phenol resin 6 | | | | |
| (B) Component | Epoxy resin 1 | 7.05 | 7.07 | | |
| | Epoxy resin 2 | | | | |
| | Epoxy resin 3 | | | | |
| | Epoxy resin 4 | | | | |
| Other epoxy resins | Epoxy resin 5 | | | 7.69 | 7.69 |
| | Epoxy resin 6 | | | | |
| (C) Component | Inorganic filler 1 | 86.5 | 86.5 | 86.5 | 86.5 |
| (D) Component | Curing accelerator 1 | 0.4 | 0.4 | 0.4 | 0.4 |
| | Curing accelerator 2 | | | | |
| (F) Component | Silane coupling agent 1 | 0.1 | 0.1 | 0.1 | 0.1 |
| | Silane coupling agent 2 | 0.05 | 0.05 | 0.05 | 0.05 |
| | Silane coupling agent 3 | 0.05 | 0.05 | 0.05 | 0.05 |
| (G) Component | Aluminum hydroxide | | | | |
| Other additives | Carbon black | 0.3 | 0.3 | 0.3 | 0.3 |
| | Carnauba wax | 0.1 | 0.1 | 0.1 | 0.1 |
| Flowability | Spiral flow [cm] | 85 | 88 | 106 | 102 |
| | Wire sweep ratio [%] | 8 | 7 | 5 | 5 |
| Flame resistance | Flame resistance test Fmax | 14 | 5 | 4 | 5 |
| | [sec] | | | | |
| | Flame resistance test ΣF | 51 | 12 | 14 | 16 |
| | [sec] | | | | |
| | Flame resistance test | V-1 | V-0 | V-0 | V-0 |
| | rank of flame resistance | | | | |
| Heat resistance | Glass transition point Tg | 166 | 163 | 139 | 138 |
| | [degrees centigrade] | | | | |
| Water absorption | Boiling water absorption | 0.153 | 0.151 | 0.123 | 0.128 |
| property | ratio [% by mass] | | | | |
| Continuous molding | Continuous molding property | Δ | Δ | Δ | Δ |
| property | | | | | |
| Solder resistance | Solder resistance test 1 | 3/6 | 3/6 | 0/6 | 0/6 |
| | [number of defective devices | | | | |
| | in n = 6] | | | | |
| | Solder resistance test 2 | 0/6 | 0/6 | 0/6 | 0/6 |
| | [number of defective devices | | | | |
| | in n = 6] | | | | |
| | Determination | x | x | ∘ | ∘ |
| High temperature | High temperature storage life | 0/10 | 0/10 | 5/10 | 6/10 |
| storage life | (HTSL) | | | | |
| | Determination | ∘ | ∘ | x | x |
| | | Comparative Example | | | |
| | | 5 | 6 | 7 | 8 |
| (A) Component | Phenol resin 1 | | | | |
| | Phenol resin 2 | 5.19 | | | |
| Other curing agents | Phenol resin 3 | | | | |
| | Phenol resin 4 | | 5.19 | | |
| | Phenol resin 5 | | | 5.54 | |
| | Phenol resin 6 | | | | 4.38 |
| (B) Component | Epoxy resin 1 | | | 6.96 | 8.12 |
| | Epoxy resin 2 | | | | |
| | Epoxy resin 3 | | | | |
| | Epoxy resin 4 | | | | |
| Other epoxy resins | Epoxy resin 5 | | | | |
| | Epoxy resin 6 | 7.31 | 7.31 | | |
| (C) Component | Inorganic filler 1 | 86.5 | 86.5 | 86.5 | 86.5 |
| (D) Component | Curing accelerator 1 | 0.4 | 0.4 | 0.4 | 0.4 |
| | Curing accelerator 2 | | | | |
| (F) Component | Silane coupling agent 1 | 0.1 | 0.1 | 0.1 | 0.1 |
| | Silane coupling agent 2 | 0.05 | 0.05 | 0.05 | 0.05 |
| | Silane coupling agent 3 | 0.05 | 0.05 | 0.05 | 0.05 |
| (G) Component | Aluminum hydroxide | | | | |
| Other additives | Carbon black | 0.3 | 0.3 | 0.3 | 0.3 |
| | Carnauba wax | 0.1 | 0.1 | 0.1 | 0.1 |
| Flowability | Spiral flow [cm] | 114 | 109 | 32 | 78 |
| | Wire sweep ratio [%] | 5 | 5 | 12 | 10 |
| Flame resistance | Flame resistance test Fmax | 1 | 1 | 5 | 30 |
| | [sec] | | | | |
| | Flame resistance test ΣF | 1 | 2 | 12 | 150 |
| | [sec] | | | | |
| | Flame resistance test | V-0 | V-0 | V-0 | Burn |
| | rank of flame resistance | | | | out |
| Heat resistance | Glass transition point Tg | 135 | 135 | 168 | 181 |
| | [degrees centigrade] | | | | |
| Water absorption | Boiling water absorption | 0.134 | 0.119 | 0.122 | 0.320 |
| property | ratio [% by mass] | | | | |
| Continuous molding | Continuous molding property | Δ | Δ | Δ | ∘ |
| property | | | | | |
| Solder resistance | Solder resistance test 1 | 0/6 | 0/6 | 3/6 | 6/6 |
| | [number of defective devices | | | | |
| | in n = 6] | | | | |
| | Solder resistance test 2 | 0/6 | 0/6 | 0/6 | 3/6 |
| | [number of defective devices | | | | |
| | in n = 6] | | | | |
| | Determination | ∘ | ∘ | x | x |
| High temperature | High temperature storage life | 8/10 | 8/10 | 0/10 | 0/10 |
| storage life | (HTSL) | | | | |
| | Determination | x | x | ∘ | ∘ |

Respective Examples 1 to 9 include a resin composition containing a phenol resin (A) containing a polymer (a1) having structural units represented by the general formula (1), an epoxy resin (B) containing at least one kind of epoxy resin selected from the group consisting of a triphenol methane type epoxy resin, a naphthol type epoxy resin and a dihydroanthracene type epoxy resin, and an inorganic filler (C), one obtained by changing the structure of naphthol of the phenol resin (A), one obtained by changing the kind of three kinds of the above epoxy resins, one obtained by changing the kind of the curing accelerator (D), and one with the addition of an inorganic flame retardant (G). The results showed that all of such resin compositions were excellent in a balance among flowability (spiral flow, wire sweep ratio), flame resistance, heat resistance (glass transition point), water absorption, continuous molding property, solder resistance and high temperature storage life.

On the other hand, the results showed that Comparative Examples 1 and 2 using the phenol resins 3 and 4 substituting alkyl-substituted phenol of the phenol resin (A) with para-cresol were inferior in the flowability (spiral flow, wire sweep ratio), continuous molding property and solder resistance. In Comparative Examples 3 and 4 using an ortho-cresol novolac type epoxy resin instead of three kinds of the above epoxy resins, the results showed that high heat resistance (glass transition point) was not achieved and high temperature storage life was inferior. Furthermore, continuous molding property was also inferior. Similarly, also in Comparative Examples 5 and 6 using a 4,4′-dimethylbiphenyl type epoxy resin instead of three kinds of the above epoxy resins, high heat resistance (glass transition point) was not achieved and high temperature storage life was inferior. Furthermore, continuous molding property was also inferior. In general, in Comparative Examples 2, 4 and 6 using the phenol resin 4 substituting alkyl-substituted phenol of the phenol resin (A) with para-cresol, the curability was slightly lowered and as a result, continuous molding property was lowered. In Comparative Example 7 using the existing co-condensation type curing agent consisting of cresol and naphthol, KAYAHARD NHN, the viscosity of the resin composition was increased so that the wire sweep ratio was extremely inferior, and solder resistance and continuous molding property were inferior. In Comparative Example 8 using both a polyfunctional epoxy resin and a polyfunctional curing agent, excellent high temperature storage life was achieved at a high glass transition point, but flame resistance and solder resistance were significantly inferior.

As shown in the above results, only a resin composition using both the phenol resin (A) and three kinds of the above epoxy resins of the present invention was excellent in a balance among flowability (spiral flow), flame resistance, glass transition point, water absorption ratio, continuous molding property, solder resistance, high temperature storage life and wire sweep ratio. More remarkable effects were resulted than expected.

According to the present invention, it is possible to obtain a resin composition for encapsulating a semiconductor which exhibits flame retardance without using a halogen compound and an antimony compound, and is excellent in a balance among solder resistance, high temperature storage life and continuous molding property at a higher level than conventional ones, so that it is suitably used for encapsulation of semiconductor devices used for electronic devices which are intended for outdoor use, in particular, semiconductor devices used for automotive electronic devices requiring high temperature storage life.

1. A resin composition for encapsulating a semiconductor comprising a phenol resin (A), an epoxy resin (B) and an inorganic filler (C), wherein said phenol resin (A) contains a polymer (a1) having a structure represented by the general formula (1), and
said epoxy resin (B) contains at least one kind of epoxy resin selected from the group consisting of a triphenol methane type epoxy resin, a naphthol type epoxy resin and a dihydroanthracene type epoxy resin, 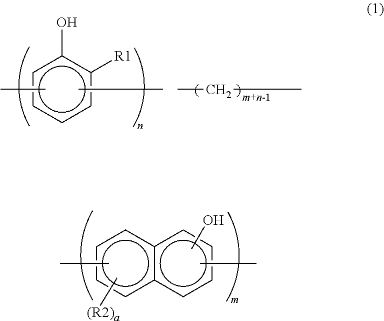
wherein, in the general formula (1), R1 is a hydrocarbon group having 1 to 6 carbon atoms; R2 is a hydrocarbon group having 1 to 6 carbon atoms or an aromatic hydrocarbon group having 6 to 14 carbon atoms, and may be the same or different from each other; a is an integer of from 0 to 2; m and n are each independently an integer of from 1 to 10; m+n is 2 or more; and the structural units represented by the repetition number m and the structural units represented by the repetition number n may be arranged in line continuously, alternately or at random, but necessarily each have a structure having —CH2- between them.

2. The resin composition for encapsulating a semiconductor according to claim 1, wherein said epoxy resin (B) comprises at least one kind of epoxy resin selected from the group consisting of an epoxy resin (b1) represented by the general formula (2), an epoxy resin (b2) represented by the general formula (3) and an epoxy resin (b3) represented by the general formula (4), 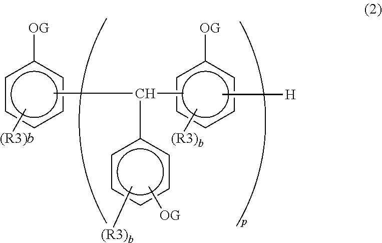
wherein, in the general formula (2), R3 is a hydrocarbon group having 1 to 6 carbon atoms or an aromatic hydrocarbon group having 6 to 14 carbon atoms, and may be the same or different from each other; b is an integer of from 0 to 4; p is an integer of from 1 to 10; and G is an organic group containing a glycidyl group, 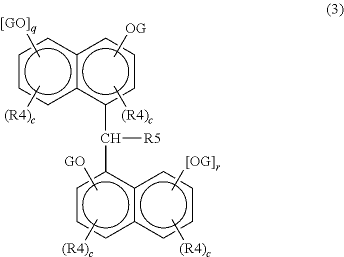
wherein, in the general formula (3), R4 is a hydrocarbon group having 1 to 6 carbon atoms or an aromatic hydrocarbon group having 6 to 14 carbon atoms, and may be the same or different from each other; R5 is a hydrogen atom, a hydrocarbon group having 1 to 6 carbon atoms or an aromatic hydrocarbon group having 6 to 14 carbon atoms; c is an integer of from 0 to 5; q and r are each independently an integer of 0 or 1; and G is an organic group containing a glycidyl group, 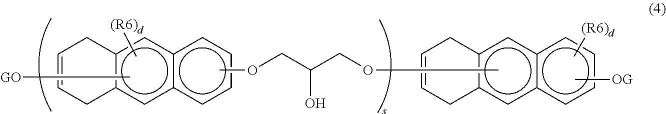
wherein, in the general formula (4), R6 is a hydrocarbon group having 1 to 6 carbon atoms or an aromatic hydrocarbon group having 6 to 14 carbon atoms, and may be the same or different from each other; d is an integer of from 0 to 8; s is an integer of from 0 to 10; and G is an organic group containing a glycidyl group.

3. The resin composition for encapsulating a semiconductor according to claim 1, wherein the ICI viscosity at 150 degrees centigrade of said phenol resin (A) is from 1.0 to 7.0 dPa·sec.

4. The resin composition for encapsulating a semiconductor according to claim 1, wherein R1 in said general formula (1) is a methyl group.

5. The resin composition for encapsulating a semiconductor according to claim 1, wherein the ratio of the polymer component in which (m,n) is (2,1) in said phenol resin (A) measured by the gel permeation chromatography (GPC) method is from 30 to 80% by area.

6. The resin composition for encapsulating a semiconductor according to claim 1, wherein said resin composition for encapsulating a semiconductor further contains a curing agent, and said phenol resin (A) is contained in an amount of 50 to 100 parts by mass in 100 parts by mass of said curing agent.

7. The resin composition for encapsulating a semiconductor according to claim 1, wherein at least one kind of said epoxy resin selected from the group consisting of a triphenol methane type epoxy resin, a naphthol type epoxy resin and a dihydroanthracene type epoxy resin is contained in an amount of 50 to 100 parts by mass in 100 parts by mass of said epoxy resin (B).

8. The resin composition for encapsulating a semiconductor according to claim 2, wherein at least one kind of said epoxy resin selected from the group consisting of said epoxy resin (b1) represented by the general formula (2), said epoxy resin (b2) represented by the general formula (3) and said epoxy resin (b3) represented by the general formula (4) is contained in an amount of 50 to 100 parts by mass in 100 parts by mass of said epoxy resin (B).

9. The resin composition for encapsulating a semiconductor according to claim 1, wherein the content ratio of said inorganic filler (C) is from 70 to 93% by mass, based on the total resin composition.

10. The resin composition for encapsulating a semiconductor according to claim 1, wherein the content ratio of said inorganic filler (C) is from 80 to 93% by mass, based on the total resin composition.

11. The resin composition for encapsulating a semiconductor according to claim 2, wherein said epoxy resin (b1) represented by the general formula (2) is contained in an amount of 50 to 100 parts by mass in 100 parts by mass of said epoxy resin (B).

12. The resin composition for encapsulating a semiconductor according to claim 1, further comprising a curing accelerator (D).

13. The resin composition for encapsulating a semiconductor according to claim 12, wherein said curing accelerator (D) comprises at least one kind of curing accelerator selected from the group consisting of a tetra-substituted phosphonium compound, a phosphobetaine compound, an adduct of a phosphine compound and a quinone compound, and an adduct of a phosphonium compound and a silane compound.

14. The resin composition for encapsulating a semiconductor according to claim 1, further comprising a compound (E) in which a hydroxyl group is bonded to each of two or more adjacent carbon atoms constituting an aromatic ring.

15. The resin composition for encapsulating a semiconductor according to claim 1, further comprising a coupling agent (F).

16. The resin composition for encapsulating a semiconductor according to claim 1, further comprising an inorganic flame retardant (G).

17. The resin composition for encapsulating a semiconductor according to claim 2, wherein said epoxy resin (b2) represented by the general formula (3) is contained in an amount of 50 to 100 parts by mass in 100 parts by mass of said epoxy resin (B).

18. The resin composition for encapsulating a semiconductor according to claim 2, wherein said epoxy resin (b3) represented by the general formula (4) is contained in an amount of 50 to 100 parts by mass in 100 parts by mass of said epoxy resin (B).

19. A semiconductor device, obtained by encapsulating a semiconductor element with a cured product of the resin composition for encapsulating a semiconductor according to claim 1.
